(19) United States
(12) Patent Application Publication
(10) Pub. No.: US 2022/0069791 A1
(43) Pub. Date: Mar. 3, 2022

(54) Multiple-Port Signal Booster

(71) Applicant: Wilson Electronics, LLC, St. George, UT (US)

(72) Inventors: Scott Terry, Norcross, GA (US); Christopher Ken Ashworth, Toquerville, UT (US)

(21) Appl. No.: 17/524,695

(22) Filed: Nov. 11, 2021

Related U.S. Application Data
(63) Continuation of application No. 16/600,315, filed on Oct. 11, 2019.
Application No. 16/600,315 is a continuation-in-part of application No. 16/555,954, filed on Aug. 29, 2019.
Application No. 16/555,954 is a continuation-in-part of application No. 16/175,670, filed on Oct. 30, 2018, now abandoned.
Application No. 16/175,670 is a continuation of application No. 15/439,554, filed on Feb. 22, 2017, now abandoned.
Application No. 16/555,954 is a continuation-in-part of application No. 15/439,554, filed on Feb. 22, 2017, now abandoned.
Application No. 15/439,554 is a continuation-in-part of application No. 14/883,539, filed on Oct. 14, 2015, now abandoned.
Application No. 14/883,539 is a continuation-in-part of application No. 14/339,098, filed on Jul. 23, 2014, now Pat. No. 9,054,664.
Application No. 16/555,954 is a continuation-in-part of application No. 14/163,566, filed on Jan. 24, 2014, now abandoned.
(60) Provisional application No. 61/842,412, filed on Jul. 3, 2013.

(51) Int. Cl. H03G 3/30; H03F 3/21; H03F 3/24; H03F 3/68; H04B 1/04; H04B 7/155; H03F 3/19

(52) U.S. Cl. CPC H03G 3/3042; H03F 3/211; H03F 3/245; H03F 3/68; H03G 3/3052; H04B 1/0475; H04B 1/18; H03F 3/19; H03F 2203/21151; H03F 2203/21142; H03F 2200/105; H03F 2200/451; H04B 7/15535

(57) ABSTRACT

A wireless repeater is disclosed. The wireless repeater can include a main booster with a first gain unit with a first adjustable gain and a second gain unit with a second adjustable gain. The wireless repeater can include a front end booster communicatively coupled to the main booster, with a coaxial cable coupled between the main booster and the front end booster. A test signal generator is configured to generate a direct current test signal or a radio frequency test signal to determine a signal loss of the coaxial cable. The wireless repeater can include a control unit to adjust one or more of the first adjustable gain or the second adjustable gain based on the determined signal loss of the coaxial cable.

### RELATED APPLICATIONS

The present application is a continuation of U.S. patent application Ser. No. 16/600,315, filed Oct. 11, 2019 with a docket number of 3969-182.NP.CIP2, which is a continuation-in-part of U.S. patent application Ser. No. 16/555,954, filed Aug. 29, 2019 with a docket number of 3969-182.NP.CIP, which is a continuation-in-part of U.S. patent application Ser. No. 14/163,566, filed Jan. 24, 2014 with a docket number of 3969-182.NP, which claims the benefit of U.S. Provisional Patent Application No. 61/842,412, filed Jul. 3, 2013. The present application also claims priority to U.S. patent application Ser. No. 16/175,670, filed Oct. 30, 2018 with a docket number of 3969-041.NP.US.DV.02.CP.C, which is a continuation application of U.S. patent application Ser. No. 15/439,554, filed Feb. 22, 2017 with a docket number of 3969-041.NP.US.DIV.02.CIP, which is a continuation-in-part of U.S. patent application Ser. No. 14/883,539, filed Oct. 14, 2015 with a docket number of 3969-041.NP.US.CIP.03, which is a continuation-in-part of U.S. patent application Ser. No. 14/339,098, filed Jul. 23, 2014 with a docket number of 3969-041.NP.US.01, the entire specifications of which are hereby incorporated by reference in their entirety for all purposes.

### TECHNICAL FIELD

The present invention relates to the field of wireless repeaters also known as boosters for wireless communication devices and, more particularly, to a multi-amplifier wireless booster system with automatic gain control for improving wireless communication service within a building, such as a home or office.

### BACKGROUND

Wireless communication systems have become widely deployed throughout the United States and abroad. A wireless repeater or booster is a radio frequency (RF) device used to amplify wireless communication signals in both uplink and downlink channels. The uplink channel is generally referred to as the direction from a mobile communication device to a base station (also referred to as a tower), while the downlink channel is generally referred to as the direction from the base station to the mobile communication device. The booster typically includes two antennas, a tower-side antenna and a mobile-side antenna, connected by coaxial cables to a base unit that includes a bi-directional amplifier (BDA) that amplifies the wireless communication signals in both directions. In certain frequency bands, the amount of amplification (gain), the maximum output power, the output noise, and other parameters associated with the operation of the booster may be limited to regulatory standards set by the government and industry. These operational limitations are typically measured from the two RF ports on the BDA that feed the coaxial cables that go to the two antennas. Meeting these operational constraints can limit the amplification that the booster is permitted to supply below the operational capability of the booster. Techniques are therefore needed for improving the operational performance of the booster while meeting the regulatory operational constraints.

### SUMMARY OF THE INVENTION

The present invention meets the needs described above in a multi-amplifier booster system that includes a remote amplifier located near one of the system antennas in addition to the bidirectional amplifier included in the base unit. Locating the remote amplifier closer to the antenna improves the system performance while allowing the booster to still meet the regulatory requirements. The base unit may also have multiple remote antenna ports on one side of the base unit allowing multiple remote antennas to be connected on that side of the base unit. A signal splitter with multiple antenna ports allows multiple remote antennas to be connected on the same side of the base unit. A remote amplifier may also be located near each remote antenna to remove the associated signal propagation losses from the regulated system performance. For this configuration, the base unit includes an amplifier detector for each remote antenna port to determine which output ports are connected to remote amplifiers. An automatic gain adjustment unit maintains the system gain, typically at the regulatory gain limit, based on the detected system configuration. The automatic gain adjustment unit typically controls the power at each output port of the base unit independently and may also control the power supplied by each remote amplifier independently.

The booster system may also include multiple antenna ports on both sides of the base unit. In this case, the base unit includes a tower-side splitter feeding multiple tower-side remote antenna ports as well as a mobile-side splitter feeding multiple mobile-side remote antenna ports. The base unit also includes multiple tower-side amplifiers, multiple tower-side amplifier detectors, multiple mobile-side amplifiers, and multiple mobile-side amplifier detectors. An automatic gain adjustment unit maintains the gain on a port-by-port basis based on the detected system configuration, which may include both tower-side and mobile-side remote amplifiers. Again for this configuration, the automatic gain adjustment unit typically controls the power at each output port of the base unit independently and may also control the power supplied by each remote amplifier independently. As an option, the uplink and downlink power may also be controlled independently.

In an alternative configuration, the remote amplifier includes an automatic gain adjustment unit that sets the gain to achieve compliance with the output constraint while offsetting the signal propagation losses determined based on test signals received from the base unit. The base unit typically sends the test signal upon detecting the presence of the remote amplifier and the sets the gain supplied to the applicable port to a moderate predetermined value selected for a port connected to the a remote amplifier. This allows the remote amplifier to set its gain based on the base unit setting its gain to the moderate predetermined value.

The specific techniques and structures for implementing particular embodiments of the multi-amplifier booster system, and thereby accomplishing the advantages described above, will become apparent from the following detailed description of the embodiments and the appended drawings and claims.

### BRIEF DESCRIPTION OF THE DRAWINGS

FIG. 1 is a conceptual block diagram showing a prior art booster for a wireless communication system.

FIG. 2 is a conceptual block diagram showing a multi-amplifier booster with one remote amplifier in addition to a base BDA unit.

FIG. 3 is a conceptual block diagram showing both a mobile-side remote amplifier and a tower-side remote amplifier in addition to the base BDA unit.

FIG. 4 is a conceptual block diagram showing a multi-amplifier booster with a signal splitter and multiple remote antennas connected to the same side of the base unit.

FIG. 5 is a conceptual block diagram showing a multi-amplifier booster with two signal splitters and multiple remote amplifiers connected to the both sides of the base unit.

FIG. 6 is a conceptual block diagram showing an alternative multi-amplifier booster having one or more remote amplifiers with automatic gain adjustment.

FIG. 7 is a logic flow diagram for operating a base unit in a wireless repeater system with one or more remote amplifiers with automatic gain adjustment.

FIG. 8 is a logic flow diagram for operating a remote amplifier with gain adjustment in a wireless repeater system.

FIG. 9 illustrates an example system with an example multiple-port signal booster.

FIG. 10 illustrates another system with another example multiple-port signal booster.

FIG. 11 illustrates an example front-end booster.

FIG. 12 illustrates another example system with another example multiple-port signal booster.

FIG. 13 is a flowchart of an example method of operating a multiple-port signal booster.

FIG. 14 is a flowchart of an example method of operating a signal booster.

### DETAILED DESCRIPTION OF THE EMBODIMENTS

Embodiments of the invention may be realized in multi-amplifier systems that include a remote amplifier located near one of the system antennas in addition to the bidirectional amplifier included in the base unit. Locating the remote amplifier closer to its respective antenna moves the RF port used to determine applicable regulatory constraints closer to the antenna. The regulatory constraints are therefore applied to the power at the remote amplifier RF output port, rather than the base unit RF output port. This effectively removes the signal propagation losses between the base unit and the remote amplifier from the limitation on booster performance caused by compliance with the regulatory constraints. The permissible power experienced at the antenna is therefore increased by the signal propagation losses between the base unit and the remote amplifier, while the booster system continues to meet the same regulatory constraints.

In a booster system utilizing a remote amplifier in addition to the base unit, the remote amplifier may be located near either the tower-side antenna or the mobile-side antenna, as desired for a particular application. Typically the remote amplifier should be positioned to remove the longest run of coaxial cable from the performance limitation. The same technique may also be utilized for both antennas resulting in a repeater system with three amplifiers: the base unit amplifier, a tower-side remote amplifier, and a mobile-side remote amplifier.

The base unit may also have multiple remote antenna ports on one side of the base unit allowing multiple remote antennas to be connected on that side of the base unit. For example, the booster system may include multiple tower-side antenna ports to allow multiple tower-side antennas to be connected to improve base station reception. As another option, the base unit may include multiple mobile-side remote ports allowing multiple mobile-side remote antennas to be connected to provide improved cellular telephone reception in multiple locations within the customer premises. To accommodate this option, the base unit includes a signal splitter with multiple antenna ports allowing multiple remote antennas to be connected on the same side of the base unit. Remote antennas may be connected to any number of the available ports. A remote amplifier may be located near one or more of the remote antenna to remove the associated signal propagation losses from the regulated system performance. The permissible gain supplied by booster system varies depending on which output ports are connected to remote amplifiers. The base unit therefore includes an amplifier detector for each remote antenna port to determine which output ports are connected to remote amplifiers. An automatic gain adjustment unit maintains the system gain, typically at the regulatory gain limit, based on the detected system configuration.

In another embodiment, the booster system may include multiple antenna ports on both sides of the base unit. In this case, the base unit includes a tower-side splitter feeding multiple tower-side remote antenna ports as well as a mobile-side splitter feeding multiple mobile-side remote antenna ports. The base unit also includes multiple tower-side amplifier detectors, multiple mobile-side amplifier detectors, and an automatic gain adjustment unit to maintain the system gain based on the detected system configuration, which may include multiple tower-side and multiple mobile-side remote amplifiers.

In the configurations described above where the automatic gain adjustment unit resides in the base unit, the base unit utilizes a predetermined signal propagation loss estimate for each remote amplifier detected. For example, the predetermined signal propagation loss estimate typically corresponds to the power losses experienced by the standard length cable that comes with the unit, such as a 25 foot length of 75 Ohm cable. However, some users may connect longer lengths of cable, for example when connecting a roof-mounted antenna to a base unit located in a basement. A typical base unit may be configured to support cable lengths up to 75 or 100 feet. In this case, the base unit may not be configured to adjust its gain to compensate for the full amount of signal loss occurring on the longer lengths of cable. It should be noted that this approach has the advantage of simplicity in that loss measurements are not necessary and the system only requires automatic gain adjustment capability in the base unit. But there is still room for improvement through additional functionality.

In particular, adding the ability to measure the actual power loss and adjust the gain accordingly provides for additional gain improvement, particularly when different lengths of cable are used to connect the remote amplifiers. An alternative configuration therefore includes one or more remote amplifiers that measure the power loss based on test signals generated by the base unit and automatically adjust their gain based on the measured signal propagation losses. As this approach may be implemented in repeaters systems with multiple remote amplifiers on the tower side, the mobile side, or both, the base unit detects the presence of remote amplifiers and implements automatic gain adjustment on a port-by-port basis.

While a DC test signal provides a good estimate of the signal losses at the RF operating frequency, the base unit may transmit an RF test signal instead of or in addition to a DC test signal. The base unit detects the presence of each remote amplifier and adjusts the gain on those ports to a moderate predetermined value for ports connected to remote amplifiers. The remote amplifier correspondingly adjusts its gain to maximum permissible level based on the assumption that the base unit gain will be set to the moderate predetermined value for ports connected to remote amplifiers. As opposed to maximizing the gain applied by the base unit, this approach reduces power losses by moderating the power transmitted over the long length of cable between the base unit and the remote amplifier.

Typically, each remote unit is configured to enter into a gain initialization mode, await test signals, and set its gain upon power up. The base unit may therefore be correspondingly configured to transmit test signals to a detected remote upon detecting the presence or powering up of the remote. Upon restart, reset, change in port status, cable connection, or any other desired condition the base unit may also be configured to ping its ports followed transmission of the test signals to cause the remote amplifiers to reinitialize their gain settings. It should be appreciated that gain adjustment protocol described above does not require the transmission of port address or any encoded information between the base unit and the remote amplifiers.

In all embodiments, the remote amplifier effectively removes the power losses on an associated coaxial cable from the power reduction experienced at an associated antenna caused by complying with the regulatory constraints. In any instance where a remote amplifier is utilized, the remote amplifier and its associated antenna may be, but does not necessarily have to be, configured as an integrated antenna/amplifier unit to further reduce the amount of coaxial cable in the system and simplify the installation. The base unit typically controls the power supplied to port independently. As a result, the gain applied in the uplink and downlink channels may be controlled independently on a port-by-port basis based on the presumed or measured signal propagation losses between the base unit and each remote amplifier.

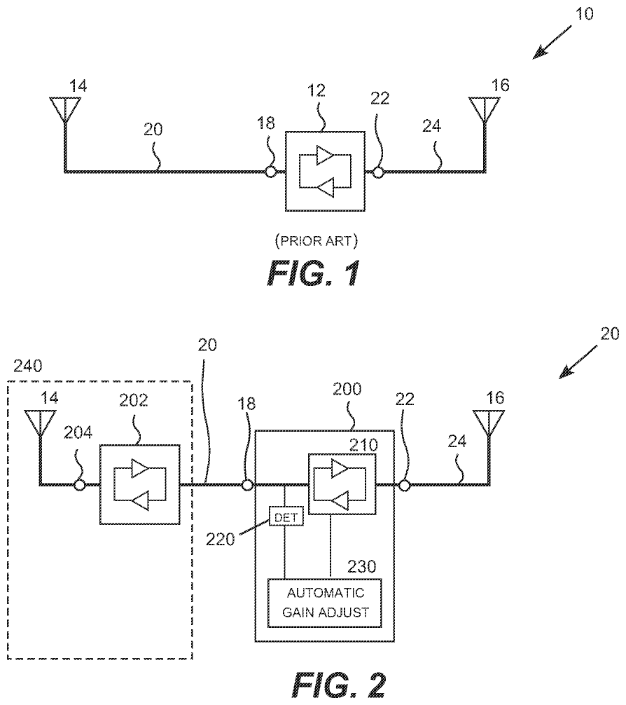

Turning now to the drawings, in which like numerals refer to like elements throughout the several figures, FIG. 1 is a conceptual block diagram showing a prior art booster 10 for a wireless communication system. The system includes a base unit 12 housing a bi-directional antenna (BDA), a tower-side antenna 14, and a mobile-side antenna 16. It will be appreciated that any functionality shown or described for the tower-side antenna may be the mobile-side antenna and vice versa. The base unit 12 has a tower-side radio frequency (RF) output port 18 and a tower-side coaxial cable 20 connecting the output port 18 to the tower-side antenna 14. Similarly, the base unit has a mobile-side RF output port 22 and a mobile-side coaxial cable 24 connecting the output port 22 to the mobile-side antenna 16. Certain regulatory constraints (e.g., output power, output noise, signal to noise ratio, etc.) applicable to the booster system 10 are determined by rule using the parameters experienced at the amplifier RF output ports 18, 22.

The specific regulatory constraints are typically met by limiting the amplification (gain) supplied by the BDA to ensure that all of the applicable constraints are satisfied. This directly limits the power available at the RF output ports 18, 22, which in turn limits the power available at the antennas 14, 16. Since the system experiences power propagation losses over the coaxial cables 20, 24, the power available at the antennas 14, 16 is reduced from the power available at the RF output ports 18, 22. These propagation losses can be significant, for example when a long run of coaxial cable is utilized to connect a roof-mounted tower-side antenna with a base unit located within the customer premises. Propagation losses can also be significant on the mobile side, for example where the base unit is located in an attic where cable access to the tower-side antenna is available and a long a long run of coaxial cable is utilized to connect the base unit to a mobile-side location in a basement office where improved wireless reception is desired. Connection guidelines typically allow on the about 75 to 100 feet of 75 Ω coaxial cable on each side of the base unit. As the maximum allowable cable runs are based on the maximum tolerable signal propagation losses, those losses can be quite significant when the installation involves anywhere near the maximum allowable cable runs.

FIG. 2 is a conceptual block diagram in which the booster of FIG. 1 has been expanded into a multi-amplifier booster 20 that includes a remote tower-side amplifier 202 located near the tower-side antenna 14. The remote tower-side amplifier 202 includes an RF port 204 where the tower-side antenna 14 connects to the remote tower-side amplifier. As an option, the remote tower-side amplifier 202 and the tower-side antenna 14 may be deployed as an integrated amplifier/antenna unit 240. The base unit 200 includes a BDA 210, a mobile-side RF port 18, a remote amplifier detector 220, and an automatic gain adjustment unit 230. The remote amplifier detector 220 detects the presence of the remote tower-side amplifier 202 connected to the coaxial cable 20, typically by detecting a change in impedance caused by the presence of the amplifier. The automatic gain adjustment unit 230 receives a remote amplifier detection signal from the detector 220 and adjusts the gain of the BDA 210 to set the gain of the BDA to a maximum level that meets the applicable regulatory operational constraints using the RF ports 22 and 204 in the applicable determinations. The automatic gain adjustment unit 230 may adjust the gain of the BDA 210, the BDA 202, or both as desired. This moves the location of the power measurement used for determining compliance with the applicable regulatory constraints on the tower side of the booster from the location of the base unit port 18 to the location of the remote amplifier port 204.

In the booster 20, the remote amplifier 202 is located closer to the tower-side antenna 14 than in the prior art configuration shown in FIG. 1. This moves the RF port 204 used to determine compliance with the regulatory constraints closer to the tower-side antenna 14 that in the conventional booster 10. The regulatory constraints are therefore applied to the power at the remote amplifier RF port 204 in the booster 20, rather than the base unit RF port 18 in the conventional booster 10. This effectively removes the signal propagation losses on the coaxial cable 20 between the base unit 200 and the remote tower-side amplifier 202 from the power reduction experienced at the tower-side antenna 14 caused by compliance with the regulatory constraints. In comparison to the conventional booster 10, the power experienced at the tower-side antenna 14 in the booster 20 is therefore increased by the signal propagation losses on the coaxial cable 20, while the booster 20 continues to meet the same regulatory constraints. In other words, the propagation losses experienced on the coaxial cable 20 have been effectively removed from the booster performance limitation caused by compliance with the regulatory constraints.

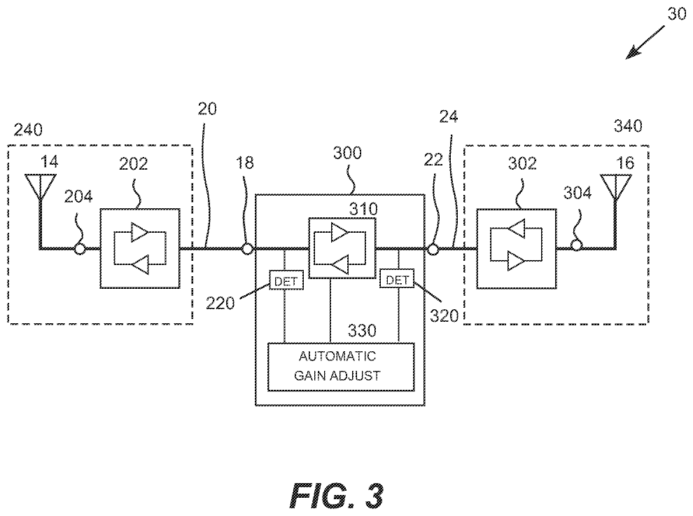

In a booster system utilizing one remote amplifier in addition to the base unit, the remote amplifier may be located near either the tower-side antenna or the mobile-side antenna, as desired for a particular application. Typically the remote amplifier should be positioned to remove the longest run of coaxial cable from the performance limitation. In addition, as shown in FIG. 3, the same technique may also be utilized for both antennas. FIG. 3 is a block diagram in which the booster of FIG. 2 has been further expanded into a repeater system 30 with three amplifiers: the base unit amplifier 300, the tower-side remote amplifier 202 located near the tower-side antenna 14, and a mobile-side remote amplifier 302 located near the mobile-side antenna 16. The remote mobile-side amplifier 302 includes an RF port 304 where the mobile-side antenna 16 connects to the remote mobile-side amplifier 302. The mobile-side remote amplifier 302 and the mobile-side antenna 16 may be configured as an integrated antenna/amplifier unit 340 to further reduce the amount of coaxial cable in the system. The remote amplifier detector 320 detects the presence of the remote mobile-side amplifier 302 connected to the coaxial cable 24, typically by detecting a change in impedance caused by the presence of the amplifier. The automatic gain adjustment unit 330 receives a remote amplifier detection signal from the detectors 220 and 320 and adjusts the gain of the BDA 310 to set the gain to a maximum level that meets the applicable regulatory operational limits using the RF ports 204 and 304 in the applicable determinations. The automatic gain adjustment unit 330 typically adjusts the power to the output ports 18 and 22 independently and may also adjust the gain of the BDAs 202 and 302 independently. The uplink gain and the downlink gain may also be controlled independently to optimize the performance of the booster while satisfying all applicable regulatory constraints.

In the booster 30 shown in FIG. 3, the remote mobile-side amplifier 302 is located closer to the mobile-side antenna 16 than in the configuration shown in FIG. 2. This moves the RF port 304 used to determine compliance with the regulatory constraints closer to the mobile-side antenna 16 than in the configuration shown in FIG. 2. The regulatory constraints are therefore applied to the power at the remote amplifier RF ports 204 and 304 in the booster 30, which effectively removes the signal propagation losses on both coaxial cables 20, 24 from the limitation on booster performance caused by compliance with the regulatory constraints. In comparison to the configuration shown in FIG. 2, the power experienced at the mobile-side antenna 16 in the booster 30 is therefore increased by the signal propagation losses on the coaxial cable 24, while the booster 30 continues to meet the same regulatory constraints.

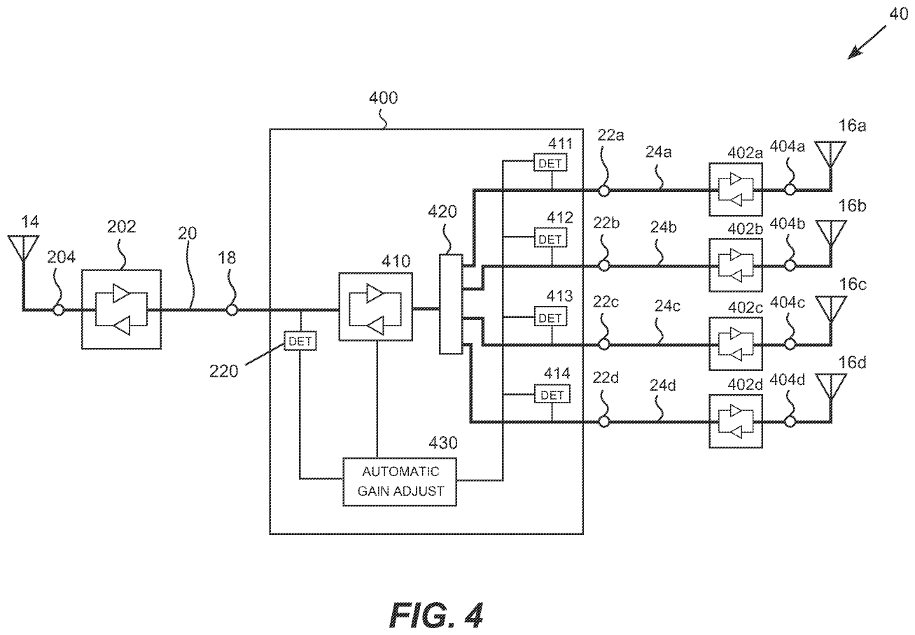

FIG. 4 is a block diagram in which the booster of FIG. 3 has been further expanded into a repeater system 40 with a signal splitter 420 and multiple remote antennas 16a-16d connected to the mobile side of the base unit 400. The base unit also includes multiple mobile-side amplifiers 402a-402d connected to respective remote antenna ports 22a-22d on the mobile side of the base unit 400. The coaxial cables 24a-24d connects the remote antenna ports 22a-22d to the respective mobile-side amplifier 402a-402d. To accommodate this option, the base unit 400 includes the signal splitter 420, which divides the mobile-side output of the BDA 410 into separate channels for the multiple antenna ports. Each remote amplifier is typically located near, and may be integral with, its respective remote mobile-side antenna to remove the associated signal propagation losses from the regulated system performance.

In this configuration, the permissible gain supplied by booster system 40 varies depending which output ports 22a-22d are connected to remote amplifiers. The base unit 400 therefore includes amplifier detectors 411, 412, 413 and 414, with one detector for each remote antenna port 22a-22d to determine the output ports that are connected to remote amplifiers on the mobile side of the base unit. The automatic gain adjustment unit 430 maintains the system gain, typically at the regulatory gain limit, based on the detected system configuration. The automatic gain adjustment unit 430 typically controls the gain supplied by the base BDA 410 to each port 402a-402d independently. The automatic gain adjustment unit 430 may also control the gain supplied by each remote mobile-side amplifier 402a-402d independently. The uplink gain and the downlink gain may also be controlled independently.

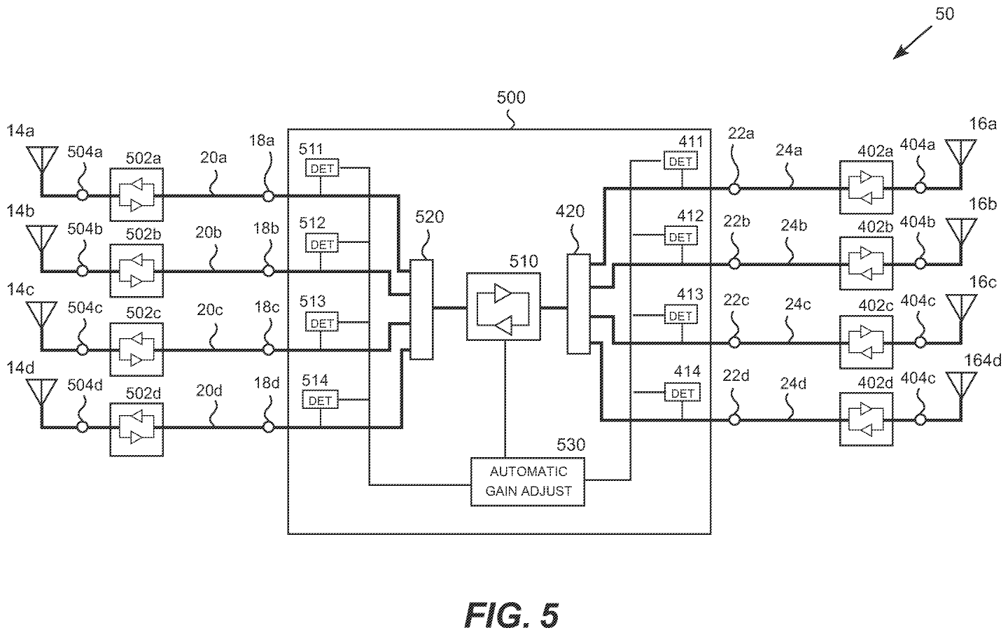

FIG. 5 is a block diagram in which the booster of FIG. 4 has been further expanded into a repeater system 50 with a second signal splitter 520 and multiple remote antennas 14a-d connected to the tower side of the base unit 500. The base unit also includes multiple tower-side amplifiers 502a-502d connected to respective remote antenna ports 18a-18d on the tower side of the base unit 500. Coaxial cables 20a-20d connect the remote antenna ports 18a-18d to respective tower-side amplifiers 502a-502d. To accommodate this option, in addition to the mobile-side splitter 420, the base unit 500 includes the tower-side splitter 520 dividing the tower-side output of the BDA 510 into separate channels for the multiple tower-side antenna ports. Again, each remote tower-side amplifier is typically located near, and may be integral with, its respective remote tower-side antenna to remove the associated signal propagation losses from the regulated system performance. In this embodiment, the permissible gain supplied by booster system 50 varies depending which output ports 18a-18d are connected to remote amplifiers. The base unit 500 therefore includes amplifier detectors 511, 512, 513 and 514, with one detector for each remote tower-side antenna port 18a-d to determine which output ports are connected to remote amplifiers connected on the tower side of the base unit. The automatic gain adjustment unit 530 maintains the system gain, typically at the regulatory gain limit, based on the detected system configuration. The propagation losses experienced on the coaxial cables 24a-d and 20a-20d are effectively removed from the booster performance limitation while the detectors 411-414 and 511-514 allow the automatic gain adjustment unit 530 to dynamically adjust the gain of the BDA 510 based on the number of mobile-side amplifiers and tower-side amplifiers actually connected to the system 50. The automatic gain adjustment unit 530 typically controls the gain supplied to each tower-side port 18a-18d and each mobile-side port 22a-22d independently. The automatic gain adjustment unit 530 may also control the gain supplied by each remote mobile-side amplifier 402a-402d and each remote tower-side amplifier 502a-502d. The uplink gain and the downlink gain may also be controlled independently.

In the configurations described with reference to FIGS. 1-5, the automatic gain adjustment unit resides in the base unit and there is no mechanism established for measuring the actual power losses on the cables between the base unit and the remote amplifiers. The base unit therefore utilizes a predetermined signal propagation loss estimate for each remote amplifier such as the losses on a standard 25 foot length of 75 Ohm cable, which may not be accurate for significantly longer lengths of cable. A typical base unit is configured to support cable lengths up to 75 to 100 feet which allows users to connect cables significantly longer than the standard 25 foot cable, as desired. When this occurs, a base unit that utilizes power loss estimates based on the standard 25 foot cable will not be configured to adjust its gain to compensate for the full amount of signal loss occurring on the longer cables.

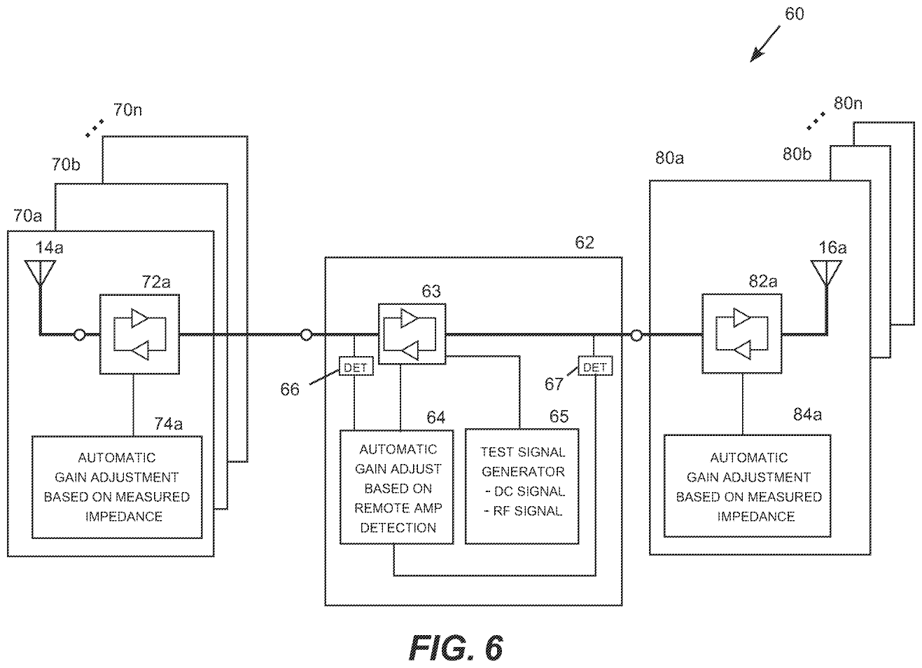

FIG. 6 is a conceptual block diagram showing an alternative multi-amplifier booster system 60 having one or more remote amplifiers 70a-n, 80a-n with automatic gain adjustment operative to measure the actual signal propagation losses and set their gain accordingly. Adding the ability of the remote amplifier to measure the actual power loss and adjust its gain to achieve compliance with the regulatory standard while offsetting the measured signal loss provides for additional gain improvement. It should be appreciated that this automatic gain adjustment technique is independent of the number of remote amplifiers connected to the base unit and may therefore be implemented on a port-by-port basis by any number of remote amplifiers. Although the base unit need not include an automatic gain adjustment unit, additional gain improvement is achieved when the base unit and the remote amplifiers include automatic gain adjustment units that are configured to operate cooperatively.

The repeater system 60 includes a base unit 62 that includes a bidirectional amplifier 63 operative to control the gain applied to one or more tower-side ports and one or more mobile-side ports on a port-by-port basis. In this particular system, the base unit also includes a gain adjustment unit 64 that adjusts the gain applied on a port-by-port basis in response to remote amplifier detection. A test signal generator 65 generates test signals at a precisely maintained test voltage and current levels that each remote amplifier measures to determine the signal propagation losses occurring on the cable between the base unit and the respective remote amplifier. The test signals typically include a DC signal and may alternatively or in addition include a test signal at the operating RF frequency suitable for determining the cable impedance and associated signal propagation losses.

A representative remote amplifier 70a includes an antenna 14a, a bidirectional amplifier 72a, and an automatic gain adjustment unit 74a. The remote amplifier determines the signal propagation losses based on the test signals received from the base unit and sets its gain accordingly, typically to the maximum level permitted by the governing regulations. In order to further reduce the signal propagation losses, the base unit is configured to set the gain supplied to a port connected to a remote amplifier connected to a moderate predetermined value. The remote amplifier is likewise configured to set its gain based on the presumption that the base unit will set its gain to the moderate predetermined value for a port connected to a remote amplifier. As opposed to maximizing the gain applied by the base unit 62, this approach reduces power losses by moderating the power transmitted over the long length of cable between the base unit and the remote amplifier 70a.

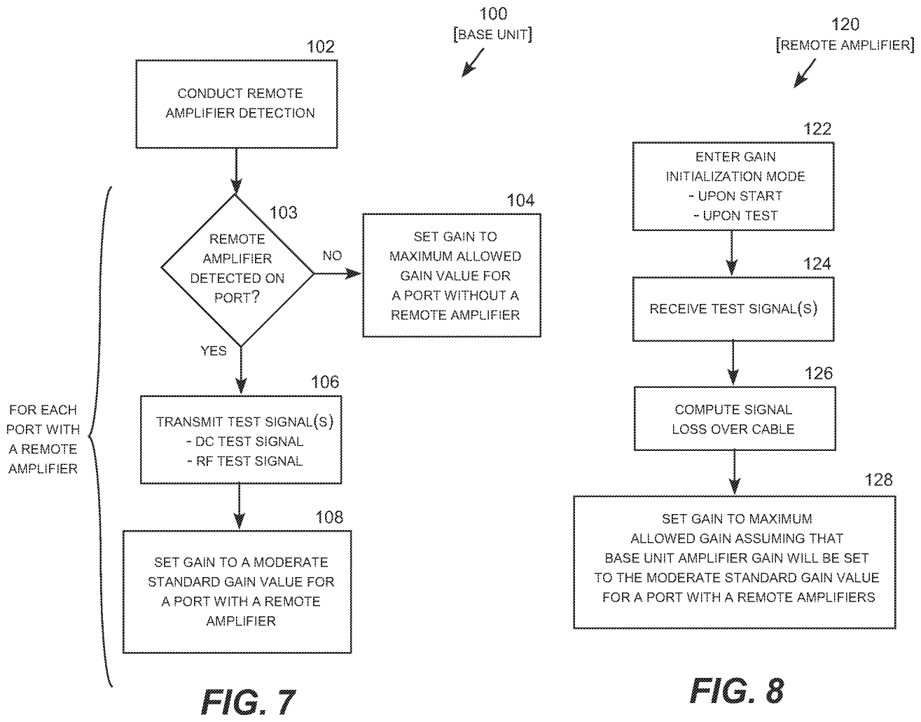

FIG. 7 is a logic flow diagram illustrating a routine 100 for operating the base unit 62. In step 102, the base unit conducts remote amplifier detection, for example by detecting a change in impedance or voltage that inherently occurs on the port whenever a remote amplifier is connected. Alternatively, the remote amplifier may be configured to transmit an initiation signal upon connection or powering up. The base unit may also be configured to send inquiries to its ports (scan for remotes) that the remotes respond to. For example, the base unit may scan for remotes whenever the base unit powers up, experiences a reset, to detect a change in an electrical parameter the voltage or impedance connected to a port.

Step 102 is followed by step 103, in which the base unit determines whether a remote amplifier has been detected on a particular port. If a remote amplifier is not detected, the “no” branch is followed to step 104 in which the base unit sets the gain on the port to the regulatory maximum for a port without a remote amplifier. Typically the base unit sets the gain for a port without a remote amplifier to offset signal propagation losses over a standard length cable, such as a 25 foot length of cable. If a remote amplifier is detected, the “yes” branch is followed to step 106 in which the base unit transmits on or more test signals over the port in accordance with the established test protocol. Step 106 is followed by step 108, in which the base unit sets the gain on the port to a moderate predetermined value for a port connected to a remote amplifier. Steps 103-108 are typically performed on a port-by-port basis for each remote amplifier connected to the base unit. It will be appreciated that this routine does not require that the base unit communicate any information other than a previously established test signal to the remote amplifier. In addition, the base unit is operative to detect the presence of the remote amplifier without receiving encoded information from the remote. As a result, there is no need for an addressing scheme, handshake or exchange of encoded information required to implement the gain control procedure.

FIG. 8 is a logic flow diagram for a routine 120 for operating the remote amplifier 70a. In step 122, the remote amplifier enters into a gain initialization mode, for example upon powering up, restart or in response to a test signal received from the base unit. Step 122 is followed by step 124, in which the remote amplifier receives the predefined test signal(s) from the base unit. Step 124 is followed by step 126, in which the remote amplifier computes the signal propagation losses over the cable between the base unit and the remote amplifier. The cable impedance may also be determined from the voltage drop caused by the test current. Step 126 is followed by step 128, in which the remote amplifier sets its gain to the desired level based on the measured signal propagation losses. In particular, the remote amplifier gain is typically set to maximum value permitted by regulation given that the base unit gain is programmed to set its gain to the moderate predetermined value established for a port connected to a remote amplifier.

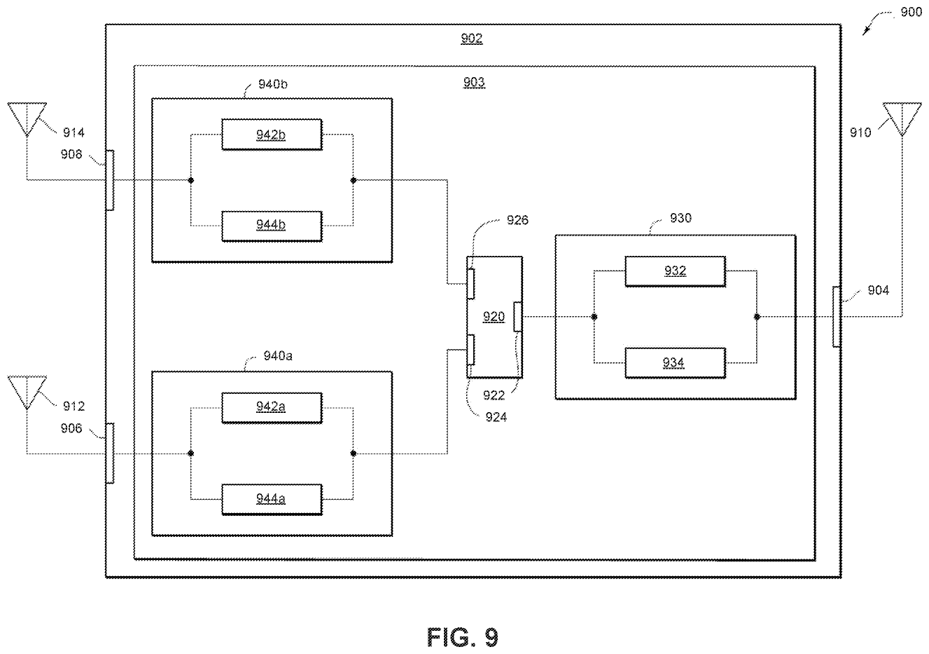

FIG. 9 illustrates an example system 900 with an example multiple-port signal booster 902, arranged in accordance with at least some embodiments described herein. In some embodiments, the system 900 may be part of a wireless communication system, and may further include first, second, and third antennas 910, 912, and 914.

The signal booster 902 may include a first interface port 904, a second interface port 906, a third interface port 908, a main booster 930, a first front-end booster 940a, and a second front-end booster 940b, referred to herein as the front-end boosters 940, and a signal splitter device 920. In some embodiments, the front-end boosters 940, the signal splitter device 920, and the main booster 930 may be coupled to a single supporting device 903. The supporting device may be a printed circuit board (PCB), a substrate, or some other supporting device.

The signal splitter device 920 may include first, second, and third splitter ports 922, 924, and 926. The main booster 930 may include a main uplink amplification path 932 and a main downlink amplification path 934. The first front-end booster 940a may include a first uplink amplification path 942a and a first downlink amplification path 944a. The second front-end booster 940b may include a second uplink amplification path 942b and a second downlink amplification path 944b.

The main booster 930 may be coupled between the first interface port 904 and the first splitter port 922. The first front-end booster 940a may be coupled between the second interface port 906 and the second splitter port 924. The second front-end booster 940b may be coupled between the third interface port 908 and the third splitter port 926. The first interface port 904 may be coupled to the first antenna 910. The second interface port 906 may be coupled to the second antenna 912. The third interface port 908 may be coupled to the third antenna 914.

In the illustrated embodiment of FIG. 9, the first antenna 910 may be configured to receive downlink signals from and transmit uplink signals to an access point. The second and third antennas 912 and 914 may be configured to receive uplink signals from and transmit downlink signals to one or more wireless devices.

The main booster 930 and the front-end boosters 940 may be configured to receive uplink and downlink signals and to apply gains to the uplink and downlink signals. In particular, the uplink amplification paths 932, 942a, and 942b may apply gains to the uplink signals and the downlink amplification paths 934, 944a, and 944b may apply gains to the downlink signals. In some embodiments, the gains applied by the uplink amplification paths 932, 942a, and 942b and the downlink amplification paths 934, 944a, and 944b may be greater than, less than, or equal to one.

The signal splitter device 920 may be configured to split downlink signals received on the first splitter port and to provide the downlink signals on both the second and third splitter ports 924 and 926. In these and other embodiments, splitting the downlink signals may replicate the data of the downlink signals such that the downlink signals on each of the second and third splitter ports 924 and 926 may include the same data. However, the signal splitter device 920 when splitting the downlink signals may reduce power levels of the downlink signals provided to the second and third splitter ports 924 and 926. For example, in some embodiments, the downlink signals on the second and third splitter ports 924 and 926 may have a power level that is reduced by 1, 3, 5, 7, 9, 10, or more decibels or some other number of decibels as compared to the power level of the downlink signals on the first splitter port 922.

The signal splitter device 920 may be further configured to combine uplink signals received on the second and third splitter ports 924 and 926 and to provide the combined uplink signals on the first splitter port 922. In these and other embodiments, the data on the uplink signals received on the second and third splitter ports 924 and 926 may be carried by the combined uplink signals on the first splitter port 922. However, the signal splitter device 920 when combining the uplink signals may reduce power levels of the uplink signals provided by the second and third splitter ports 924 and 926. For example, in some embodiments, the combined uplink signals on the first splitter port 922 may have a power level that is reduced by 1, 3, 5, 7, 9, 10, or more decibels or some other number of decibels as compared to the power level of the uplink signals on the second and third splitter ports 924 and 926.

In some embodiments, the signal splitter device 920 may be an active or passive device. Alternately or additionally, the signal splitter device 920 may include one or more of a signal splitter, a coupler, a tap, a resistive splitter, and a Wilkinson divider, or some combination thereof.

In general, the front-end boosters 940 may be configured to apply a gain to the uplink and downlink signals to compensate for a reduction in power levels of the uplink and downlink signals caused by the signal splitter device 920. In this configuration, the main booster 930 may be configured to apply a general amplification to the uplink and downlink signals based on configurations of the wireless communication network in which the signal booster 902 is operating. For example, the main booster 930 may operate to increase or decrease a gain applied to the uplink and downlink signals based on noise levels at the access point, government regulations, and wireless communication operator regulations, among others. In short, the main booster 930 may apply any known algorithm or scheme to apply gain to downlink and uplink signals to enhance or otherwise make communications between a wireless device and an access point function within the constraints of the wireless communications network in which the signal booster 902 is operating.

A description of the operation of the system 900 with respect to uplink and downlink signals follows. Downlink signals may be received by the first antenna 910 from an access point and provided to the main booster 930. The main booster 930 may provide the downlink signals to the downlink amplification path 934. The downlink amplification path 934 may apply a gain to the downlink signals based on the characteristics of the wireless communication network in which the system 900 is operating. The main booster 930 may provide the downlink signals to the first splitter port 922 of the signal splitter device 920.

The signal splitter device 920 may provide the downlink signals on both the second and third splitter ports 924 and 926, such that the downlink signals are provided to both the front-end boosters 940. The downlink amplification paths 944 of the front-end boosters 940 may apply a gain to the downlink signals and provide the downlink signals to the second and third antennas 912 and 914, respectively. In these and other embodiments, the second and third antennas 912 and 914 may be positioned in separate locations to serve different wireless devices. For example, the second antenna 912 may be in a first portion of a building and may provide the downlink signals to wireless devices in the first portion of the building. The third antenna 914 may be in a second portion of the building and may provide the downlink signal to wireless devices in the second portion of the building.

First uplink signals from one or more first wireless devices may be received at the second antenna 912 and provided to the first front-end booster 940a. The first uplink amplification path 942a may apply a gain to the first uplink signals and may provide the first uplink signals to the second splitter port 924 of the signal splitter device 920.

Second uplink signals from one or more second wireless devices may be received at the third antenna 914 and provided to the second front-end booster 940b. The second uplink amplification path 942b may apply a gain to the second uplink signals and may provide the second uplink signals to the third splitter port 926 of the signal splitter device 920.

The signal splitter device 920 may combine the first and second uplink signals and provide the combined uplink signals to the main booster 930. The main booster 930 may provide the combined uplink signals to the uplink amplification path 932. The uplink amplification path 932 may apply a gain to the combined uplink signals based on the characteristics of the wireless communication network in which the system 900 is operating. The main booster 930 may provide the combined uplink signals to the first antenna 910 for transmission to an access point.

Without the front-end boosters 940, the noise level of uplink signal would increase based on the loss of the signal splitter device 920. Furthermore, without the front-end boosters 940, the signal power of the downlink systems would decrease based on the loss of the signal splitter device 920. In some countries, governmental agencies or other rule making bodies may limit the gain of the main booster 930. As a result, without the front-end boosters 940, compensation for the losses associated with the signal splitter device 920 may not be made. To avoid these losses without using the front-end boosters 940, two separate boosters, similar to the main booster 930 may be used. However, in some circumstances, using the system 900 as illustrated may result in lower costs than two separate boosters. Furthermore, the system 900 may be simpler and provide for integrated communication between the main booster 930 and the front-end boosters 940.

Modifications, additions, or omissions may be made to the system 900 without departing from the scope of the present disclosure. For example, in some embodiments, the signal booster 902 may include additional interface ports that are coupled to antennas that are configured to communicate with wireless devices. In these and other embodiments, each of the interface ports may be coupled to a front-end booster similar to the front-end boosters 940. Alternately or additionally, in some embodiments, the signal booster 902 may not include a front-end booster for each of the interface ports that is coupled to an antenna that communicates with wireless devices. For example, in some embodiments, the signal booster 902 may not include one of the first or second front-end boosters 940.

Furthermore, the signal booster 902 may include multiple other front-end boosters and main boosters. As illustrated, the signal booster 902 may operate to apply gains to a single band of signals in a wireless communication system. In other embodiments, the signal booster 902 may operate to apply gains to multiple bands of signals in a wireless communication system. In these and other embodiments, the signal boosters may include a main booster and front-end boosters as illustrated for every band.

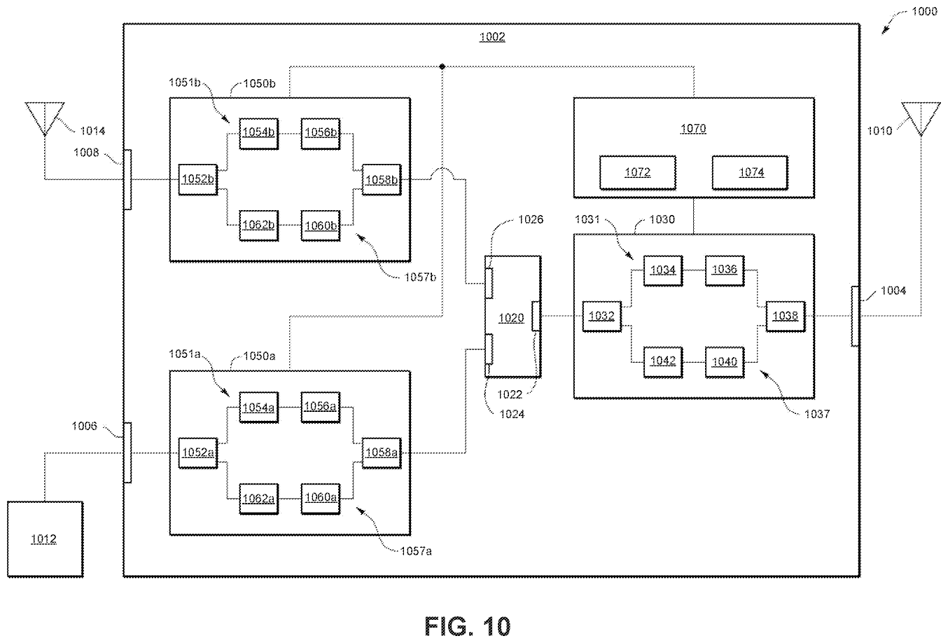

FIG. 10 illustrates another example system 1000 that includes another example multiple-port signal booster 1002. In some embodiments, the system 1000 may be part of a wireless communication system. The system 1000 may include first and second antennas 1010 and 1014 and a communication device 1012.

The signal booster 1002 may include a first interface port 1004, a second interface port 1006, a third interface port 1008, a main booster 1030, a first front-end booster 1050a, and a second front-end booster 1050b, referred to herein as the front-end boosters 1050, a signal splitter device 1020, and a control unit 1070.

The signal splitter device 1020 may include first, second, and third splitter ports 1022, 1024, and 1026. The main booster 1030 may include a main uplink amplification path 1031 and a main downlink amplification path 1037. The first front-end booster 1050a may include a first front-end uplink amplification path 1051a and a first front-end downlink amplification path 1057a. The second front-end booster 1050b may include a second front-end uplink amplification path 1051b and a second front-end downlink amplification path 1057b.

The main booster 1030 may be coupled between the first interface port 1004 and the first splitter port 1022. The first front-end booster 1050a may be coupled between the second interface port 1006 and the second splitter port 1024. The second front-end booster 1050b may be coupled between the third interface port 1008 and the third splitter port 1026. The first interface port 1004 may be coupled to the first antenna 1010. The second interface port 1006 may be coupled to the communication device 1012. The third interface port 1008 may be coupled to the second antenna 912. The communication device 1012 may be any device that is configured to receive communication signals. For example, the communication device 1012 may be a computing device, such as a computer, a modem, or some other type of device.

In the illustrated embodiment of FIG. 10, the first antenna 1010 may be configured to receive downlink signals from and transmit uplink signals to an access point. The second antenna 912 may be configured to receive uplink signals from and transmit downlink signals to one or more wireless devices.

The main booster 1030 and the front-end boosters 1050 may be configured to receive uplink and downlink signals and to apply a gain to the uplink and downlink signals. In particular, the main and front-end uplink amplification paths 1031, 1051a, and 1051b may be configured to apply gains to the uplink signals and the main and front-end downlink amplification paths 1037, 1057a, and 1057b may be configured to apply gains to the downlink signals. In some embodiments, the gains applied by the main and front-end uplink amplification paths 1031, 1051a, and 1051b and the main and front-end downlink amplification paths 1037, 1057a, and 1057b may be greater than, less than, or equal to one.

The main uplink amplification path 1031 may include a first main duplexer 1032, a main uplink gain unit 1034, a main uplink signal power level detector 1036 (referred to herein as the main uplink detector 1036), and a second main duplexer 1038. The main downlink amplification path 1037 may include the first main duplexer 1032, a main downlink gain unit 1040, a main downlink signal power level detector 1042 (referred to herein as the main downlink detector 1042), and the second main duplexer 1038.

The main uplink gain unit 1034 and the main downlink gain unit 1040 may be configured to apply gains to the uplink and downlink signals, respectively, in the main booster 1030. In some embodiments, the gain applied by the main uplink gain unit 1034 and the main downlink gain unit 1040 may be controlled by the control unit 1070. As a result, the main uplink gain unit 1034 and the main downlink gain unit 1040 may adjust the gains applied to the uplink and downlink signals, respectively, in the main booster 1030 based on instructions, such as a control signal, from the control unit 1070.

The main uplink detector 1036 and the main downlink detector 1042 may be configured to detect a power level of uplink and downlink signals, respectively, in the main booster 1030. The main uplink detector 1036 and the main downlink detector 1042 may be configured to provide the detected power levels to the control unit 1070 as the main uplink and downlink power levels.

The first front-end uplink amplification path 1051a may include a first front-end duplexer 1052a, a first front-end uplink gain unit 1054a, a first front-end uplink signal power level detector 1056a (referred to herein as the first uplink detector 1056a), and a second front-end duplexer 1058a. The first front-end downlink amplification path 1057a may include the first front-end duplexer 1052a, a first front-end downlink gain unit 1060a, a first front-end downlink signal power level detector 1062a (referred to herein as the first downlink detector 1062a), and the second front-end duplexer 1058a.

The first front-end uplink gain unit 1054a and the first front-end downlink gain unit 1060a may be configured to apply gains to the uplink and downlink signals, respectively, in the first front-end booster 1050a. In some embodiments, the gains applied by the first front-end uplink gain unit 1054a and the first front-end downlink gain unit 1060a may be controlled by the control unit 1070. As a result, the first front-end uplink gain unit 1054a and the first front-end downlink gain unit 1060a may adjust the gains applied to the uplink and downlink signals, respectively, in the first front-end booster 1050a based on instructions, such as a control signal, from the control unit 1070.

The first uplink detector 1056a and the first downlink detector 1062a may be configured to detect a power level of the uplink and downlink signals, respectively, in the first front-end booster 1050a. The first uplink detector 1056a and the first downlink detector 1062a may be configured to provide the detected power levels to the control unit 1070 as the first uplink and downlink power levels.

The second front-end uplink amplification path 1051b may include a third front-end duplexer 1052b, a second front-end uplink gain unit 1054b, a second front-end uplink signal power level detector 1056b (referred to herein as the second uplink detector 1056b), and a fourth front-end duplexer 1058b. The second front-end downlink amplification path 1057b may include the third front-end duplexer 1052b, a second front-end downlink gain unit 1060b, a second front-end downlink signal power level detector 1062b (referred to herein as the second downlink detector 1062b), and the fourth front-end duplexer 1058b.

The second front-end uplink gain unit 1054b and the second front-end downlink gain unit 1060b may be configured to apply gains to uplink and downlink signals, respectively, in the second front-end booster 1050b. In some embodiments, the gains applied by the second front-end uplink gain unit 1054b and the second front-end downlink gain unit 1060b may adjust the gains applied to the uplink and downlink signals, respectively, in the second front-end booster 1050b based on instructions, such as a control signal, from the control unit 1070.

The second uplink detector 1056b and the second downlink detector 1062b may be configured to detect a power level of the uplink and downlink signals, respectively, in the second front-end booster 1050b. The second uplink detector 1056b and the second downlink detector 1062b may be configured to provide the detected power levels to the control unit 1070 as the second uplink and downlink power levels.

The control unit 1070 may be coupled to the main booster 1030, the first front-end booster 1050a, and the second front-end booster 1050b. The control unit 1070 may be configured to receive the main uplink and downlink power levels from the main booster 1030, the first uplink and downlink power levels from the first front-end booster 1050a, and the second uplink and downlink power levels from the second front-end booster 1050b. Collectively, the main uplink and downlink power levels, the first uplink and downlink power levels, and the second uplink and downlink power levels may be referred to herein as the detected power levels.

The control unit 1070 may be configured to determine gains that are applied by the main booster 1030 and the front-end boosters 1050 to uplink and downlink signals based on the detected power levels. For example, when the main downlink power level is a first power level, the control unit 1070 may set the gain of the main downlink gain unit 1040 to a first gain. Alternately or additionally, when the main downlink power level is a second power level, the control unit 1070 may set the gain of the main downlink gain unit 1040 to a second gain.

The gains selected by the control unit 1070 to be applied by the main booster 1030 based on the detected power levels may be configured such that the uplink and downlink signals may be transmitted between an access point and wireless devices, respectively, with SNRs that are sufficient for wireless communications between the access point and the wireless devices. Furthermore, the control unit 1070 may select the gain to apply to the main booster 1030 based on other factors in a wireless network that includes the system 1000. For example, the control unit 1070 may select the gains for the main booster 1030 based on providing noise floor, internal oscillation, external oscillation (e.g., antenna to antenna oscillations), and/or overload protection for the wireless network.

The control unit 1070 may be further configured to adjust the gains applied to the front-end boosters 1050 based on the detected power levels. For example, in some embodiments, the control unit 1070 may be configured to adjust the gain applied by the first and second front-end uplink gain units 1054a and 1054b based on the first and second uplink power levels. In these and other embodiments, the control unit 1070 may adjust the gain applied by the first and second front-end uplink gain units 1054a and 1054b such that a power level of a first uplink signal output by the first front-end booster 1050a is equal to or approximately equal to a power level of a second uplink signal output by the second front-end booster 1050b. A power level of the first uplink signal being approximately equal to a power level of the second uplink signal may indicate that the power levels are within 20% of each other.

By adjusting the gains applied by the front-end boosters 1050 such that the first and second uplink signals have equal or approximately equal power levels when received by the main booster 1030, the main booster 1030 may apply a gain to the first and second uplink signals that assists both of the first and second uplink signals being received by an access point with appropriate SNR levels. For example, assume that the first uplink signal has a higher power level than the second uplink signal when received by the signal booster 1002. If both of the front-end boosters 1050 applied equal or approximately equal gains to the first and second uplink signals, the first and second uplink signals would be received by the main booster 1030 with the first uplink signal having a higher power level than the second uplink signal. The main booster 1030 may apply a gain for both the first and second uplink signals based on the highest power level of the first and second uplink signals. Thus, the main booster 1030 may apply a gain to both the first and second uplink signals that is configured for the first uplink signal and not the second uplink signal. As a result, the gain applied by the main booster 1030 may be sufficient to allow the first uplink signal to reach an access point with an appropriate SNR but may not be sufficient to allow the second uplink signal to reach the access point with the appropriate SNR. By configuring the front-end boosters 1050 to apply gains to the first and second uplink signals such that the power levels of the first and second uplink signals are equal or approximately equal, the gain applied by the main booster 1030 may be sufficient for both the first and second uplink signals to reach the access point with the appropriate SNR.

Alternately or additionally, in some embodiments, the control unit 1070 may be configured to adjust the gain applied by the first and second front-end downlink gain units 1060a and 1060b based on the first and second downlink power levels. In these and other embodiments, the control unit 1070 may be configured to adjust the gain applied by the first and second front-end downlink gain units 1060a and 1060b based on the first and second downlink power levels such that a power level of a first downlink signal output by the first front-end booster 1050a is equal to or approximately equal to a power level of a second downlink signal output by the second front-end booster 1050b. Alternately or additionally, the control unit 1070 may be configured to have the first and second front-end downlink gain units 1060a and 1060b apply a constant gain based on signal losses caused by the signal splitter device 1020.

In one example, the control unit 1070 can identify a signal loss of the signal splitter device 1020. The control unit 1070 can control the first and second front-end downlink gain units 1060a and 1060b to compensate for the signal loss of the signal splitter device 1020. Further, the control unit 1070 can identify the signal loss of the signal splitter device 1020 based on a known signal loss or a predetermined signal loss caused by the signal splitter device 1020.

As mentioned above, the control unit 1070 may be further configured to detect oscillations in the signal booster 1002 based on the detected power levels. In these and other embodiments, the control unit 1070 may detect internal oscillations that may occur within the main booster 1030 or the front-end boosters 1050. For example, an internal oscillation in the main booster 1030 may occur when one or both of the first and second main duplexers 1032 and 1038 does not provide adequate isolation between the main uplink amplification path 1031 and the main downlink amplification path 1037. As a result, the uplink signals and/or the downlink signals may traverse both of the main uplink amplification path 1031 and the main downlink amplification path 1037, resulting in an internal oscillation in the main booster 1030. Similar internal oscillations may occur in the front-end boosters 1050.

The control unit 1070 may be further configured to detect external, otherwise referred to port-to-port or parasitic oscillations that may occur within the signal booster 1002. During an external oscillation, an uplink signal and/or a downlink signal that is output by one of the first, second, or third interface port 1004, 1006, and 1008 is received at another of the first, second, or third interface port 1004, 1006, and 1008. As a result, the uplink signal and/or the downlink signal may be continually amplified and result in an external oscillation. For example, an uplink signal transmitted by the first antenna 1010 may be received by the second antenna 1014 and the gain of the signal booster 902 may again be applied to the uplink signal such that the power level of the uplink signal increases. This sequence of events is repeated such that the uplink signal has a high gain that results in excessive noise in a wireless network that includes the system 1000.

The control unit 1070 may be configured to detect internal or external oscillations in the signal booster 1002 based on the detected power levels. In particular, the control unit 1070 may be configured to detect oscillations in each of the main booster 1030 and the front-end boosters 1050. For each of the main boosters 1030 and the front-end boosters 1050, the control unit 1070 may detect oscillations by comparing one or more detected power levels at a first time to detected power levels at a second time using any number of oscillation detection schemes. For example, the control unit 1070 may detect oscillations in the main booster 1030 by collecting first detected power levels of an uplink signal at a first time and collecting second detected uplink power levels of the uplink signal at a second time. Using the first and second uplink detected power levels, the control unit 1070 may determine the peak-to-average power ratio (PAPR) of the uplink signal and compare the PAPR to a threshold. When the PAPR is less than a threshold, the control unit 1070 may determine that the main booster 1030 is oscillating.

After determining whether the main booster 1030 and/or the front-end boosters 1050 are oscillating, the control unit 1070 may determine whether the oscillations are internal or external oscillations. When only one of the main booster 1030, the first front-end booster 1050a, and the second front-end booster 1050b is oscillating, the oscillation may be an internal oscillation of the oscillating main booster 1030, the oscillating first front-end booster 1050a, or the oscillating second front-end booster 1050b. In these and other embodiments, the control unit 1070 may adjust the gain applied by the oscillating main booster 1030, the oscillating first front-end booster 1050a, or the oscillating second front-end booster 1050b to stop the internal oscillation. In particular, the control unit 1070 may reduce the gain applied by the oscillating main booster 1030, the oscillating first front-end booster 1050a, or the oscillating second front-end booster 1050b to stop the internal oscillation. In these and other embodiments, the control unit 1070 may direct that the gain be reduced to zero or near zero to stop the internal oscillation.

For external oscillations, at least the main booster 1030 and one of the front-end boosters 1050 may be oscillating. In these and other embodiments, the control unit 1070 may adjust the gain applied by the main booster 1030 to stop the external oscillation. In particular, the control unit 1070 may reduce the gain applied by the main booster 1030 to stop the external oscillation. In these and other embodiments, the control unit 1070 may direct that the gain be reduced to zero or near zero to stop the external oscillation.

Alternately or additionally, the control unit 1070 may adjust the gain applied by the oscillating front-end boosters 1050 to stop the external oscillation. In particular, the control unit 1070 may reduce the gain applied by the oscillating front-end boosters 1050 to stop the external oscillation. If only one of the two front-end boosters 1050 is oscillating, by adjusting the gain applied by the oscillating front-end boosters 1050 and not the main booster 1030, the main booster 1030 and the other non-oscillating front-end boosters 1050 may continue to operate normally without a reduced gain. Alternately or additionally, the control unit 1070 may adjust the gain applied by the front-end boosters 1050 that are oscillating and the main booster 1030 to stop the external oscillation.

In some embodiments, the control unit 1070 may be implemented by any suitable mechanism, such as a program, software, function, library, software as a service, analog, or digital circuitry, or any combination thereof. For example, the control unit 1070 may include a processor 1072 and memory 1074. The processor 1072 may include, for example, a microprocessor, microcontroller, digital signal processor (DSP), application-specific integrated circuit (ASIC), a Field-Programmable Gate Array (FPGA), or any other digital or analog circuitry configured to interpret and/or to execute program instructions and/or to process data. In some embodiments, the processor 1072 may interpret and/or execute program instructions and/or process data stored in the memory 1074. The instructions may include instructions for adjusting the gain of the main booster 1030 and/or one or more of the front-end boosters 1050, among other instructions.

The memory 1074 may include any suitable computer-readable media configured to retain program instructions and/or data for a period of time. By way of example, and not limitation, such computer-readable media may include tangible and/or non-transitory computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, flash memory devices (e.g., solid state memory devices), or any other storage medium which may be used to carry or store desired program code in the form of computer-executable instructions or data structures and which may be accessed by a general-purpose or special-purpose computer. Combinations of the above may also be included within the scope of computer-readable media. Computer-executable instructions may include, for example, instructions and data that cause a general-purpose computer, special-purpose computer, or special-purpose processing device to perform a certain function or group of functions.

Modifications, additions, or omissions may be made to the system 1000 without departing from the scope of the present disclosure. For example, in some embodiments, the signal booster 1002 may include additional interface ports that are coupled to antennas that are configured to communicate with wireless devices. In these and other embodiments, each of the interface ports may be coupled to a front-end booster similar to the front-end boosters 1050. Alternately or additionally, in some embodiments, the signal booster 1002 may not include a front-end booster for each of the interface ports that is coupled to an antenna that communicates with wireless devices. For example, in some embodiments, the signal booster 502 may not include one of the first or second front-end boosters 1050.

Furthermore, the signal booster 1002 may include multiple other front-end boosters and main boosters. As illustrated, the signal booster 1002 may operate to apply gains to a single band of signals in a wireless communication system. In other embodiments, the signal booster 1002 may operate to apply gains to multiple bands of signals in a wireless communication system. In these and other embodiments, the signal boosters may include a main booster and front-end boosters as illustrated for every band. In these and other embodiments, the control unit 1070 may be coupled to each of the main and front-end boosters in each of the bands. Alternately or additionally, each of the main and front-end boosters in each of the bands may be associated with a separate control unit.

In some embodiments, the front-end boosters 1050 may not include the first downlink detector 1062a and/or the second downlink detector 1062b. In these and other embodiments, the control unit 1070 may adjust the gain of the first and second front-end downlink gain units 1060a and 1060b based on other detected power levels or the loss of the signal splitter device 1020.

In one configuration, the first front-end uplink gain unit 1054a can be referred to as a first gain unit, the first front-end uplink signal power level detector 1056a can be referred to as a first signal power level detector, the first front-end downlink signal power level detector 1062a can be referred to as a fifth signal power level detector, and the first front-end downlink gain unit 1060a can be referred to as a fifth gain unit.

Moreover, the second front-end uplink gain unit 1054b can be referred to as a second gain unit, the second front-end uplink signal power level detector 1056b can be referred to as a second signal power level detector, the second front-end downlink signal power level detector 1062b can be referred to as a sixth signal power level detector, and the second front-end downlink gain unit 1060b can be referred to as a sixth gain unit.

Moreover, the main uplink gain unit 1034 can be referred to as a third gain unit, the main uplink signal power level detector 1036 can be referred to as a third signal power level detector, the main downlink signal power level detector 1042 can be referred to as a fourth gain unit, and the main downlink gain unit 1040 can be referred to as a fourth signal power level detector. In addition, the signal splitter device 1020 can be referred to as a signal combiner device.

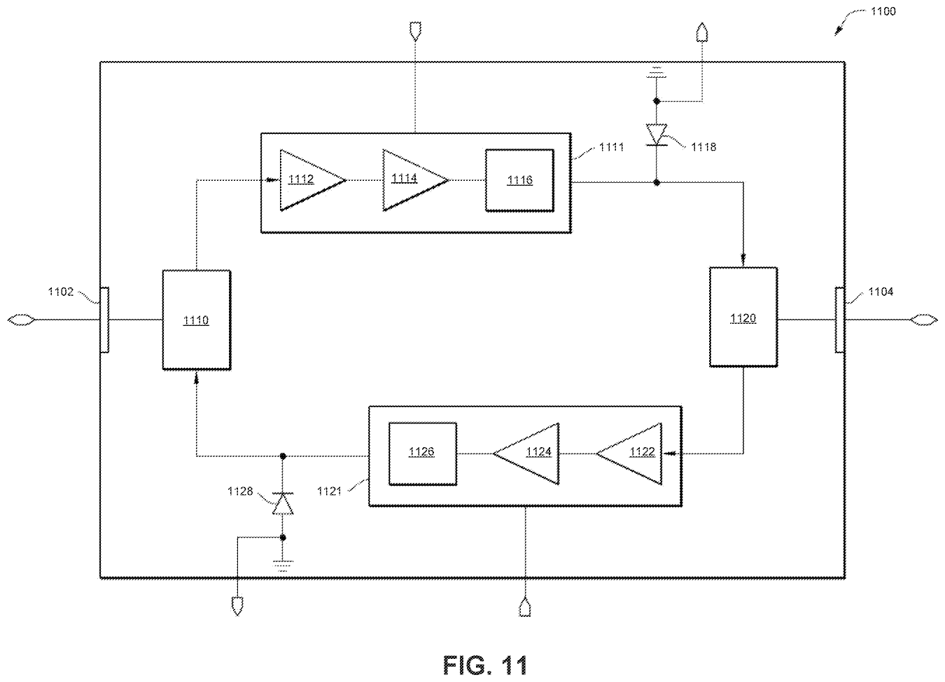

FIG. 11 illustrates an example front-end booster 1100 (referred to herein as “the booster 1100”), arranged in accordance with at least one embodiment described herein. In some embodiments, the booster 1100 may be part of a signal booster.

The booster 1100 includes a first interface port 1102, a second interface port 1104, a first duplexer 1110, a second duplexer 1120, a first gain unit 1111, a first diode 1118, a second gain unit 1121, and a second diode 1128.

The first duplexer 1110 may be coupled between the first interface port 1102, the first gain unit 1111, and the second gain unit 1121. The second duplexer 1120 may be coupled between the second interface port 1104, the first gain unit 1111, and the second gain unit 1121. The first diode 1118 may be coupled between the first gain unit 1111 and the second interface port 1104. The second diode 1128 may be coupled between the second gain unit 1121 and the first interface port 1102.

The first gain unit 1111 may include a first amplifier 1112, a second amplifier 1114, and a first attenuator 1116. One or more of the first amplifier 1112, the second amplifier 1114, and/or the first attenuator 1116 may be adjustable such that the gain of the first gain unit 1111 may be adjustable. For example, in some embodiments, a control unit, may send a signal to the first gain unit 1111 to adjust the attenuation of the first attenuator 1116 to thereby adjust the gain of the first gain unit 1111.

The second gain unit 1121 may include a third amplifier 1122, a fourth amplifier 1124, and a second attenuator 1126. One or more of the third amplifier 1122, the fourth amplifier 1124, and/or the second attenuator 1126 may be adjustable such that the gain of the second gain unit 1121 may be adjustable. For example, in some embodiments, a control unit may send a signal to the second gain unit 1121 to adjust the gain of the third amplifier 1122 to thereby adjust the gain of the second gain unit 1121

In some embodiments, the first and second diodes 1118 and 1128 may be examples of a signal power level detector. In these and other embodiments, the first and second diodes 1118 and 1128 may provide indications of power levels of signals within the booster 1100.

An example of the operation of the booster 1100 follows. A first direction signal may be received on the first interface port 1102 and be directed to the first gain unit 1111 by the first duplexer 1110. The first direction signal may be amplified by the first and second amplifiers 1112 and 1114 and then attenuated by the first attenuator 1116. The amplified first direction signal may be provided to the second duplexer 1120. As the first direction signal passes the first diode 1118, the first diode 1118 may generate a current that is based on the power level of the first direction signal. The second duplexer 1120 may direct the first direction signal to the second interface port 1104.

At the same time, before, or after the first direction signal is received at the first interface port 1102, a second direction signal may be received at the second interface port 1104 and be directed to the second gain unit 1121 by the second duplexer 1120. The second direction signal may be amplified by the third and fourth amplifiers 1122 and 1124 and then attenuated by the second attenuator 1126. The amplified second direction signal may be provided to the first duplexer 1110. As the second direction signal passes the second diode 1128, the second diode 1128 may generate a current that is based on the power level of the second direction signal. The first duplexer 1110 may direct the second direction signal to the first interface port 1102.

Modifications, additions, or omissions may be made to the booster 1100 without departing from the scope of the present disclosure. For example, in some embodiments, the booster 1100 may not include the second diode 1128.

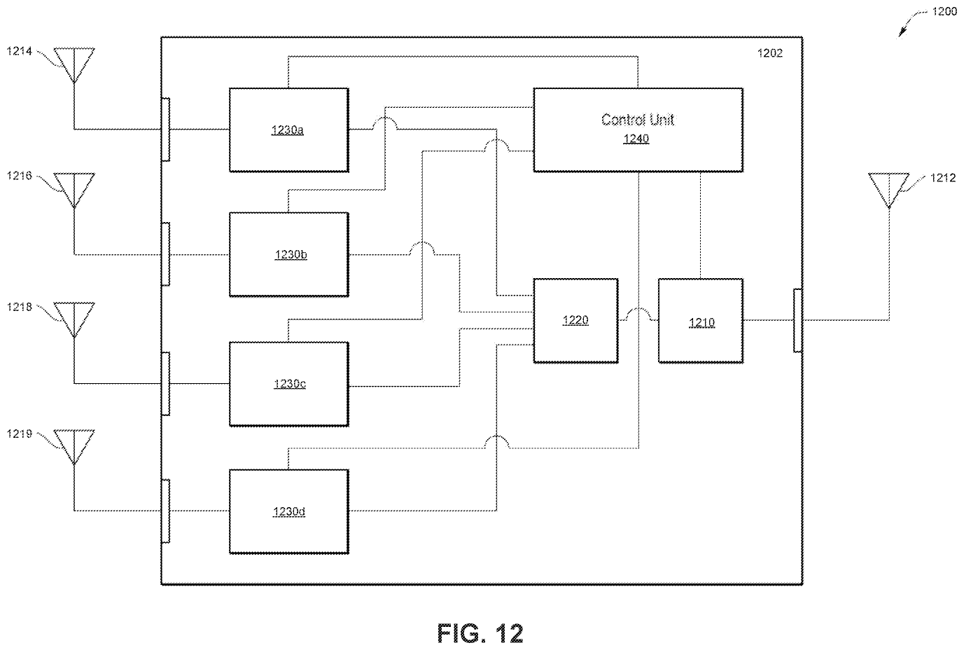

FIG. 12 illustrates an embodiment of another system 1200 with another example multiple-port signal booster, arranged in accordance with at least some embodiments described herein. The system 1200, however, may include first, second, third, fourth, and fifth antennas 1212, 1214, 1216, 1218, and 1219. The first antenna 1212 may be configured to communicate with an access point. The second, third, fourth, and fifth antennas 1214, 1216, 1218, and 1219 may be configured to communicate with wireless devices. The signal booster 1202, as illustrated in FIG. 12, may include a main booster 510, a signal splitter device 1220, first, second, third, and fourth front-end boosters, 1230a, 1230b, 1230c, and 1230d, referred to as the front-end boosters 1230, and a control unit 1240. Each of the front-end boosters 1230 may be configured to receive uplink signals from and send downlink signals to one of the second, third, fourth, and fifth antennas 1214, 1216, 1218, and 1219 as illustrated.

The main booster 510 and the front-end boosters 1230 may operate to apply gains to uplink and downlink signals as described herein previously. The control unit 1240 may operate to control the gains applied by the main booster 510 and the front-end boosters 1230.

Modifications, additions, or omissions may be made to the system 1200 without departing from the scope of the present disclosure. For example, in some embodiments, the signal booster 1202 may include additional interface ports that are coupled to antennas that are configured to communicate with wireless devices. In these and other embodiments, each of the interface ports may be coupled to a front-end booster similar to the front-end boosters 1230. Alternately or additionally, in some embodiments, the signal booster 1202 may not include a front-end booster for each of the interface ports that is coupled to an antenna that communicates with wireless devices. For example, in some embodiments, the signal booster 1202 may not include one of the front-end boosters 1230.

Furthermore, the signal booster 1202 may include multiple other front-end boosters and main boosters. As illustrated, the signal booster 1202 may operate to apply gains to a single band of signals in a wireless communication system. In other embodiments, the signal booster 1202 may operate to apply gains to multiple bands of signals in a wireless communication system. In these and other embodiments, the signal booster 1202 may include a main booster and front-end boosters as illustrated for every band.

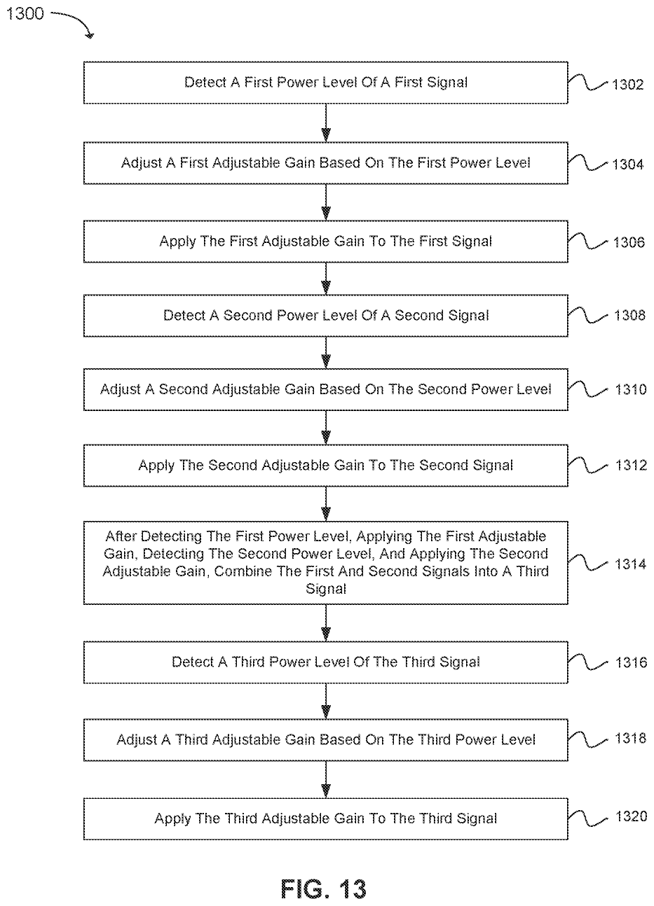

FIG. 13 is a flowchart of an example method 1300 of operating a multiple-port signal booster, arranged in accordance with at least some embodiments described herein. The method 1300 may be implemented, in some embodiments, by a signal booster. Although illustrated as discrete blocks, various blocks may be divided into additional blocks, combined into fewer blocks, or eliminated, depending on the desired implementation.

The method 1300 may begin at block 1302, where a first power level of a first signal may be detected. In block 1304, a first adjustable gain may be adjusted based on the first power level.

In block 1306, the first adjustable gain may be applied to the first signal. In block 1308, a second power level of a second signal may be detected. In block 1310, a second adjustable gain may be adjusted based on the second power level. In block 1312, the second adjustable gain may be applied to the second signal.

In block 1314, after detecting the first power level, applying the first adjustable gain, detecting the second power level, and applying the second adjustable gain, the first and second signals may be combined into a third signal.

In block 1316, a third power level of the third signal may be detected. In block 1318, a third adjustable gain may be adjusted based on the third power level. In block 1320, the third adjustable gain may be applied to the third signal.

In one example, the method 1300 may further include comparing the first power level to the second power level. The first adjustable gain may be adjusted based on the comparison and the first power level and the second adjustable gain may be adjusted based on the comparison and the second power level. The first and second adjustable gains may be adjusted such that the first power level and the second power level are approximately equal.

In one example, the method 1300 may further include detecting an oscillation based on the detected first power level or the detected second power level. Alternately or additionally, the method 1300 may further include reducing the third adjustable gain based on a detected oscillation.

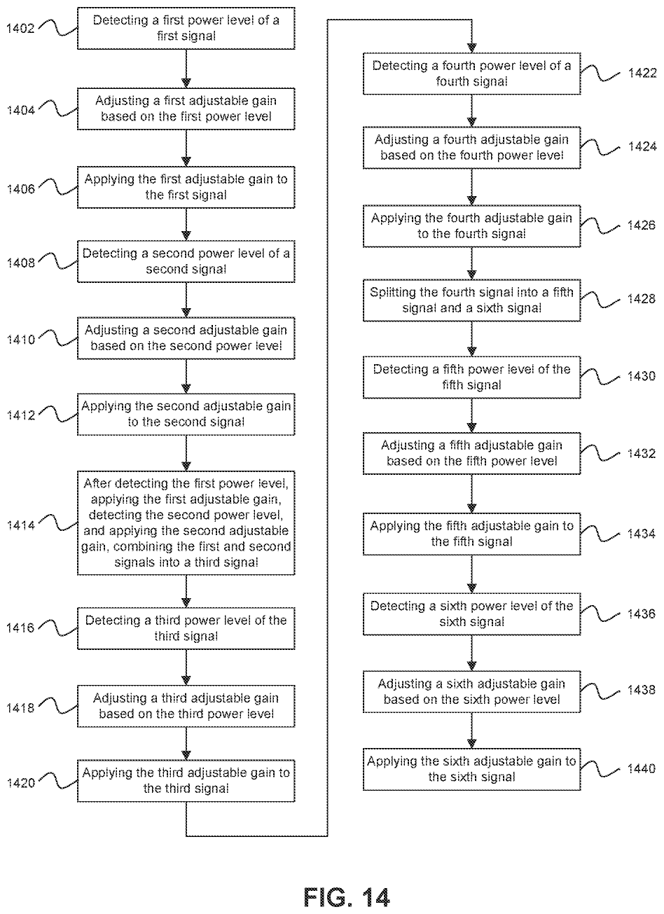

FIG. 14 is a flowchart of an example method of operating a signal booster. The method can include the operation of: detecting a first power level of a first signal, as in block 1402. The method can include the operation of: adjusting a first adjustable gain based on the first power level, as in block 1404. The method can include the operation of: applying the first adjustable gain to the first signal, as in block 1406. The method can include the operation of: detecting a second power level of a second signal, as in block 1408. The method can include the operation of: adjusting a second adjustable gain based on the second power level, as in block 1410. The method can include the operation of: applying the second adjustable gain to the second signal, as in block 1412. The method can include the operation of: after detecting the first power level, applying the first adjustable gain, detecting the second power level, and applying the second adjustable gain, combining the first and second signals into a third signal, as in block 1414. The method can include the operation of: detecting a third power level of the third signal, as in block 1416. The method can include the operation of: adjusting a third adjustable gain based on the third power level, as in block 1418. The method can include the operation of: applying the third adjustable gain to the third signal, as in block 1420.

Furthermore, the method can include the operation of: detecting a fourth power level of a fourth signal, as in block 1422. The method can include the operation of: adjusting a fourth adjustable gain based on the fourth power level, as in block 1424. The method can include the operation of: applying the fourth adjustable gain to the fourth signal, as in block 1426. The method can include the operation of: splitting the fourth signal into a fifth signal and a sixth signal, as in block 1428. The method can include the operation of: detecting a fifth power level of the fifth signal, as in block 1430. The method can include the operation of: adjusting a fifth adjustable gain based on the fifth power level, as in block 1432. The method can include the operation of: applying the fifth adjustable gain to the fifth signal, as in block 1434. The method can include the operation of: detecting a sixth power level of the sixth signal, as in block 1436. The method can include the operation of: adjusting a sixth adjustable gain based on the sixth power level, as in block 1438. The method can include the operation of: applying the sixth adjustable gain to the sixth signal, as in block 1440.

### EXAMPLES

The following examples pertain to specific technology embodiments and point out specific features, elements, or actions that can be used or otherwise combined in achieving such embodiments.

Example 1 includes a wireless repeater comprising: a first antenna; a second antenna; a first remote amplifier connected to the first antenna; a base unit configured to supply amplified wireless communication signals to the first and second antennas in uplink and downlink channels, the base unit comprising a bidirectional amplifier having one or more output ports; a first cable connecting a first output port of the base unit to the first remote amplifier; the base unit further comprising a first detector operative for detecting the connection of the first remote amplifier to the first output port; the base unit further comprising an automatic gain adjustment unit operative for adjusting a first gain supplied to the first output port to achieve compliance with an output constraint while offsetting expected signal propagation losses on the first cable.

Example 2 includes the wireless repeater of Example 1, wherein the first antenna is a tower-side antenna and the second antenna is a mobile-side antenna.

Example 3 includes the wireless repeater of any of Examples 1 to 2, wherein the first antenna is a mobile-side antenna and the second antenna is a tower-side antenna.

Example 4 includes the wireless repeater of any of Examples 1 to 3, wherein the base unit is further operative for setting gains supplied to multiple tower-side ports to offset expected signal losses on multiple cables connected to multiple tower-side remote amplifiers.

Example 5 includes the wireless repeater of any of Examples 1 to 4, wherein the base unit is further operative for setting gains supplied to multiple mobile-side ports to offset expected signal losses on multiple cables connected to multiple mobile-side remote amplifiers.

Example 6 includes the wireless repeater of any of Examples 1 to 5, wherein the expected signal losses on the first cable are based on a standard length of cable expected to be connected between the remote amplifier and the first output port.

Example 7 includes the wireless repeater of any of Examples 1 to 6, wherein the output constraint is based on a regulatory standard.

Example 8 includes the wireless repeater of any of Examples 1 to 7, further comprising: a second remote amplifier connected to the second remote antenna; a second cable connecting a second output port of the base unit to the second remote amplifier; the base unit further comprising a second detector operative for detecting the connection of the second remote amplifier to the second output port; wherein the base unit automatic gain adjustment unit is further operative for adjusting a second gain supplied to the second output port to achieve compliance with the output constraint while offsetting expected signal losses on the second cable.

Example 9 includes the wireless repeater of any of Examples 1 to 8, wherein the base unit is further operative for setting gains supplied to multiple tower-side ports to offset expected signal losses on multiple cables connected to multiple tower-side remote amplifiers.

Example 10 includes the wireless repeater of any of Examples 1 to 9, wherein the base unit is further operative for setting gains supplied to multiple mobile-side ports to offset expected signal losses on multiple cables connected to multiple mobile -side remote amplifiers.

Example 11 includes the wireless repeater of any of Examples 1 to 10, wherein the base unit is further operative for setting gains supplied to multiple tower-side ports to offset expected signal losses on multiple cables connected to multiple tower-side remote amplifiers, and for setting gains supplied to multiple mobile-side ports to offset expected signal losses on multiple cables connected to multiple mobile-side remote amplifiers.

Example 12 includes the wireless repeater of any of Examples 1 to 11, wherein the test signal comprises a DC test signal.

Example 13 includes the wireless repeater of any of Examples 1 to 12, wherein the test signal comprises an RF test signal at an operational frequency of the wireless repeater.

Example 14 includes a wireless repeater comprising: a first antenna; a second antenna; a remote amplifier connected to the first antenna; a base unit configured to supply amplified wireless communication signals to the first and second antennas in uplink and downlink channels, the base unit comprising a base unit bidirectional amplifier having one or more output ports; a cable connecting a first output port of the base unit to the remote amplifier; the base unit operative for transmitting a test signal to the remote amplifier; the remote amplifier comprising an automatic gain adjustment unit operative for determining signal propagation losses on the cable based on the test signal and adjusting a gain supplied to the first antenna to achieve compliance with an output constraint while offsetting the signal propagation losses.

Example 15 includes the wireless repeater of Example 14, wherein: the base unit further comprises a detector operative for detecting the connection of the remote amplifier to the first output port; the base unit further comprises an automatic gain adjustment unit operative for responding to the detection of the remote amplifier by setting a gain supplied to the first output port to a predetermined moderate value for a port connected to a remote amplifier; the remote amplifier is further operative for setting its gain based on the base unit gain supplied to the remote amplifier being set to the predetermined moderate value for a port connected to a remote amplifier.

Example 16 includes the wireless repeater of any of Examples 14 to 15, wherein the base unit is further operative for transmitting the test signal on the first output port in response to detecting the connection of the remote amplifier to the first output port.

Example 17 includes the wireless repeater of any of Examples 14 to 16, comprising multiple tower-side remote amplifiers that are each connected to the base unit and operative for determining signal propagation losses based a test signal received from the base unit and adjusting a gain supplied to an associated antenna to achieve compliance with an output constraint while offsetting the signal propagation losses.

Example 18 includes the wireless repeater of any of Examples 14 to 17, further comprising multiple mobile-side remote amplifiers that are each connected to the base unit and operative for determining signal propagation losses based a test signal received from the base unit and adjusting a gain supplied to an associated antenna to achieve compliance with an output constraint while offsetting the signal propagation losses.

Example 19 includes the wireless repeater of any of Examples 14 to 18, wherein the test signal comprises a DC test signal.

Example 20 includes the wireless repeater of any of Examples 14 to 19, wherein the test signal comprises an RF test signal at an operational frequency of the wireless repeater.

Example 21 includes a multiple-port signal booster, comprising: a first front-end booster including: a first signal power level detector configured to detect a first power level of a first signal; and a first gain unit with a first adjustable gain configured to be applied to the first signal, the first adjustable gain adjusted based on the first power level; a second front-end booster including: a second signal power level detector configured to detect a second power level of a second signal; and a second gain unit with a second adjustable gain configured to be applied to the second signal, the second adjustable gain adjusted based on the second power level; a signal combiner device configured to: receive the first signal after the application of the first adjustable gain; receive the second signal after the application of the second adjustable gain; and combine the first and second signals to form a third signal; and a main booster including: a third signal power level detector configured to detect a third power level of the third signal; and a third gain unit with a third adjustable gain configured to be applied to the third signal, the third adjustable gain adjusted based on the third power level, wherein the main booster further includes: a fourth signal power level detector configured to detect a fourth power level of a fourth signal; and a fourth gain unit with a fourth adjustable gain configured to be applied to the fourth signal, the fourth adjustable gain adjusted based on the fourth power level; wherein the signal combiner device is further configured to: receive the fourth signal after the application of the fourth adjustable gain; and split the fourth signal into a fifth signal and a sixth signal; wherein the first front-end booster further includes: a fifth signal power level detector configured to detect a fifth power level of the fifth signal; and a fifth gain unit with a fifth adjustable gain configured to be applied to the fifth signal, the fifth adjustable gain adjusted based on the fifth power level; wherein the second front-end booster further includes: a sixth signal power level detector configured to detect a sixth power level of the sixth signal; and a sixth gain unit with a sixth adjustable gain configured to be applied to the sixth signal, the sixth adjustable gain adjusted based on the sixth power level; and wherein the multiple-port signal booster further comprises a control unit configured to adjust the fifth adjustable gain of the first front-end booster and the sixth adjustable gain of the second front-end booster based on a signal loss of the signal combiner device.

Example 22 includes the multiple-port signal booster of Example 21, wherein the control unit is configured to adjust the first adjustable gain and the second adjustable gain based on the signal loss of the signal combiner device.

Example 23 includes the multiple-port signal booster of any of Examples 21 to 22, wherein the control unit is coupled to the first gain unit, the second gain unit, the first signal power level detector, and the second signal power level detector, the control unit configured to receive the first power level and the second power level and to adjust the first adjustable gain and the second adjustable gain.

Example 24 includes the multiple-port signal booster of any of Examples 21 to 23, wherein the control unit is coupled to the fifth gain unit, the sixth gain unit, the fifth signal power level detector, and the sixth signal power level detector, the control unit configured to receive the fifth power level and the sixth power level and to adjust the fifth adjustable gain and the sixth adjustable gain.

Example 25 includes the multiple-port signal booster of any of Examples 21 to 24, wherein the control unit is configured to: adjust the first adjustable gain and the second adjustable gain to cause the first power level and the second power level to be approximately equal; and adjust the fifth adjustable gain and the sixth adjustable gain to cause the fifth power level and the sixth power level to be approximately equal.

Example 26 includes the multiple-port signal booster of any of Examples 21 to 25, wherein the first signal, the second signal, and the third signal are downlink signals or uplink signals.

Example 27 includes the multiple-port signal booster of any of Examples 21 to 26, wherein the signal combiner device is an active or passive device and includes one or more of a signal splitter, a coupler, a tap, a resistive splitter, and a Wilkinson divider.

Example 28 includes the multiple-port signal booster of any of Examples 21 to 27, wherein the first signal, the second signal, and the third signal are uplink signals, wherein the signal combiner device is configured to split a fourth signal into a fifth signal and a sixth signal, the fourth signal, the fifth signal, and the sixth signal being downlink signals.

Example 29 includes the multiple-port signal booster of any of Examples 21 to 28, wherein each of the first gain unit, the second gain unit, and the third gain unit includes an amplifier chain that includes one or more amplifiers and a variable attenuator.

Example 30 includes a method, comprising: detecting, using a control unit of a multiple-port signal booster, a first power level of a first signal; adjusting a first adjustable gain based on the first power level; applying the first adjustable gain to the first signal; detecting a second power level of a second signal; adjusting a second adjustable gain based on the second power level; applying the second adjustable gain to the second signal; after detecting the first power level, applying the first adjustable gain, detecting the second power level, and applying the second adjustable gain, combining the first and second signals into a third signal; detecting a third power level of the third signal; adjusting a third adjustable gain based on the third power level; applying the third adjustable gain to the third signal; detecting a fourth power level of a fourth signal; adjusting a fourth adjustable gain based on the fourth power level; applying the fourth adjustable gain to the fourth signal; splitting the fourth signal into a fifth signal and a sixth signal; detecting a fifth power level of the fifth signal; adjusting a fifth adjustable gain based on the fifth power level; applying the fifth adjustable gain to the fifth signal; detecting a sixth power level of the sixth signal; adjusting a sixth adjustable gain based on the sixth power level; applying the sixth adjustable gain to the sixth signal; and adjusting the fifth adjustable gain and the sixth adjustable gain based on a signal loss.

Example 31 includes the method of Example 30, wherein the fifth and sixth adjustable gains are adjusted such that the fifth power level and the sixth power level are approximately equal.

Example 32 includes the method of any of Examples 30 to 31, further comprising: detecting an oscillation based on the fifth power level or the sixth power level; and reducing the fourth adjustable gain based on a detected oscillation.

Example 33 includes the method of any of Examples 30 to 32, further comprising comparing the first power level to the second power level, wherein the first adjustable gain is adjusted based on the comparison and the first power level and the second adjustable gain is adjusted based on the comparison and the second power level.

Example 34 includes the method of any of Examples 30 to 33, wherein the first and second adjustable gains are adjusted such that the first power level and the second power level are approximately equal.

Example 35 includes the method of any of Examples 30 to 34, further comprising detecting an oscillation based on the first power level or the second power level.

Example 36 includes the method of any of Examples 30 to 35, further comprising reducing the third adjustable gain based on a detected oscillation.

Example 37 includes at least one non-transitory machine readable storage medium having instructions embodied thereon, the instructions when executed by a control unit of a multiple-port signal booster perform the following: detecting a first power level of a first signal; adjusting a first adjustable gain based on the first power level; applying the first adjustable gain to the first signal; detecting a second power level of a second signal; adjusting a second adjustable gain based on the second power level; applying the second adjustable gain to the second signal; after detecting the first power level, applying the first adjustable gain, detecting the second power level, and applying the second adjustable gain, combining the first and second signals into a third signal; detecting a third power level of the third signal; adjusting a third adjustable gain based on the third power level; applying the third adjustable gain to the third signal; detecting a fourth power level of a fourth signal; adjusting a fourth adjustable gain based on the fourth power level; applying the fourth adjustable gain to the fourth signal; splitting the fourth signal into a fifth signal and a sixth signal; detecting a fifth power level of the fifth signal; adjusting a fifth adjustable gain based on the fifth power level; applying the fifth adjustable gain to the fifth signal; detecting a sixth power level of the sixth signal; adjusting a sixth adjustable gain based on the sixth power level; applying the sixth adjustable gain to the sixth signal; and adjusting the fifth adjustable gain and the sixth adjustable gain based on a signal loss.

Example 38 includes the at least one non-transitory machine readable storage medium of Example 37, wherein the fifth and sixth adjustable gains are adjusted such that the fifth power level and the sixth power level are approximately equal.

Example 39 includes the at least one non-transitory machine readable storage medium of any of Examples 37 to 38, further comprising instructions when executed perform the following: detecting an oscillation based on the fifth power level or the sixth power level; and reducing the fourth adjustable gain based on a detected oscillation.

Example 40 includes the at least one non-transitory machine readable storage medium of any of Examples 37 to 39, further comprising instructions when executed perform the following: comparing the first power level to the second power level, wherein the first adjustable gain is adjusted based on the comparison and the first power level and the second adjustable gain is adjusted based on the comparison and the second power level.

Example 41 includes the at least one non-transitory machine readable storage medium of any of Examples 37 to 40, wherein the first and second adjustable gains are adjusted such that the first power level and the second power level are approximately equal.

Example 42 includes the at least one non-transitory machine readable storage medium of any of Examples 37 to 41, further comprising instructions when executed perform the following: detecting an oscillation based on the first power level or the second power level.

Example 43 includes the at least one non-transitory machine readable storage medium of any of Examples 37 to 42, further comprising instructions when executed perform the following: reducing the third adjustable gain based on a detected oscillation.

Example 44 includes a wireless repeater, comprising: a first front-end booster; a second front-end booster; a main booster; a first antenna communicatively coupled to the first front-end booster; a second antenna communicatively coupled to the second front-end booster; a third antenna communicatively coupled to the main booster; a signal combiner device communicatively coupled between the main booster and the first front-end booster and the second front-end booster; a coaxial cable communicatively coupled to the signal combiner device, wherein the coaxial cable is between the signal combiner device and the main booster, or the coaxial cable is between the signal combiner device and the first front-end booster or the second front-end booster; and a control unit configured to adjust an adjustable gain of the first front-end booster, an adjustable gain of the second front-end booster, or an adjustable gain of the main booster based on an expected signal loss of at least one of the signal combiner device or the coaxial cable.

Example 45 includes the wireless repeater of Example 44, wherein: the first front-end booster includes: a first signal power level detector configured to detect a first power level of a first signal; and a first gain unit with a first adjustable gain configured to be applied to the first signal, the first adjustable gain adjusted based on the first power level; the second front-end booster includes: a second signal power level detector configured to detect a second power level of a second signal; and a second gain unit with a second adjustable gain configured to be applied to the second signal, the second adjustable gain adjusted based on the second power level; the signal combiner device is configured to: receive the first signal after the application of the first adjustable gain; receive the second signal after the application of the second adjustable gain; and combine the first and second signals to form a third signal; and the main booster includes: a third signal power level detector configured to detect a third power level of the third signal; and a third gain unit with a third adjustable gain configured to be applied to the third signal, the third adjustable gain adjusted based on the third power level, wherein the main booster further includes: a fourth signal power level detector configured to detect a fourth power level of a fourth signal; and a fourth gain unit with a fourth adjustable gain configured to be applied to the fourth signal, the fourth adjustable gain adjusted based on the fourth power level; wherein the signal combiner device is further configured to: receive the fourth signal after the application of the fourth adjustable gain; and split the fourth signal into a fifth signal and a sixth signal; wherein the first front-end booster further includes: a fifth signal power level detector configured to detect a fifth power level of the fifth signal; and a fifth gain unit with a fifth adjustable gain configured to be applied to the fifth signal, the fifth adjustable gain adjusted based on the fifth power level; wherein the second front-end booster further includes: a sixth signal power level detector configured to detect a sixth power level of the sixth signal; and a sixth gain unit with a sixth adjustable gain configured to be applied to the sixth signal, the sixth adjustable gain adjusted based on the sixth power level; and wherein the control unit is configured to adjust the fifth adjustable gain of the first front-end booster and the sixth adjustable gain of the second front-end booster based on the expected signal loss of the signal combiner device.

Example 46 includes the wireless repeater of Example 45, wherein the control unit is configured to adjust the first adjustable gain and the second adjustable gain based on the expected signal loss of the signal combiner device.

Example 47 includes the wireless repeater of any of Examples 45 to 46, wherein the control unit is coupled to the first gain unit, the second gain unit, the first signal power level detector, and the second signal power level detector, the control unit configured to receive the first power level and the second power level and to adjust the first adjustable gain and the second adjustable gain.

Example 48 includes the wireless repeater of any of Examples 45 to 47, wherein the control unit is coupled to the fifth gain unit, the sixth gain unit, the fifth signal power level detector, and the sixth signal power level detector, the control unit configured to receive the fifth power level and the sixth power level and to adjust the fifth adjustable gain and the sixth adjustable gain.

Example 49 includes the wireless repeater of any of Examples 45 to 46, wherein the control unit is configured to: adjust the first adjustable gain and the second adjustable gain to cause the first power level and the second power level to be approximately equal; and adjust the fifth adjustable gain and the sixth adjustable gain to cause the fifth power level and the sixth power level to be approximately equal.

Example 50 includes the wireless repeater of any of Examples 45 to 49, wherein the first signal, the second signal, and the third signal are downlink signals or uplink signals.

Example 51 includes the wireless repeater of any of Examples 45 to 50, wherein the signal combiner device is an active or passive device.

Example 52 includes the wireless repeater of any of Examples 45 to 51, wherein the signal combiner device includes one or more of a signal splitter, a coupler, a tap, a resistive splitter, or a Wilkinson divider.

Example 53 includes the wireless repeater of any of Examples 45 to 52, wherein the first signal, the second signal, and the third signal are uplink signals, wherein the signal combiner device is configured to split a fourth signal into a fifth signal and a sixth signal, the fourth signal, the fifth signal, and the sixth signal being downlink signals.

Example 54 includes the wireless repeater of any of Examples 45 to 53, wherein each of the first gain unit, the second gain unit, and the third gain unit includes an amplifier chain that includes one or more amplifiers and a variable attenuator.

Example 55 includes a wireless repeater, comprising: a first interface port; a second interface port; a third interface port; a first gain unit with a first adjustable gain configured to be applied to a first-direction signal; a second gain unit with a second adjustable gain configured to be applied to a second-direction signal; a signal splitter comprising: a first splitter port; a second splitter port; and a third splitter port, wherein: the first gain unit and the second gain unit are communicatively coupled between the first interface port the first splitter port; the second splitter port is communicatively coupled to the second interface port; and the third splitter port is communicatively coupled to the third interface port; and a control unit communicatively coupled to the first gain unit and the second gain unit, the control unit configured to: control the first adjustable gain and the second adjustable gain to compensate for a signal loss of the signal splitter.

Example 56 includes the wireless repeater of Example 55, wherein the control unit is configured to identify the signal loss of the signal splitter based on a known signal loss or a predetermined signal loss caused by the signal splitter.

Example 57 includes the wireless repeater of any of Examples 55 to 56, the signal splitter is a passive device.

Example 58 includes the wireless repeater of any of Examples 55 to 57, wherein the signal splitter is configured to combine a plurality of first-direction signals or a plurality of second-direction signals.

Example 59 includes the wireless repeater of any of Examples 55 to 58, wherein the signal splitter is a 4-port signal splitter, wherein the 4-port signal splitter includes an access point port, a first wireless device port, a second wireless device port, a third wireless device port and a fourth wireless device port.

Example 60 includes the wireless repeater of any of Examples 55 to 59, wherein: the access point port is configured to be communicatively coupled to an access point antenna via the wireless repeater; the first wireless device port is configured to be communicatively coupled to a first wireless device antenna; the second wireless device port is configured to be communicatively coupled to a second wireless device antenna; the third wireless device port is configured to be communicatively coupled to a third wireless device antenna; and the fourth wireless device port is configured to be communicatively coupled to a fourth wireless device antenna.

Example 61 includes the wireless repeater of any of Examples 55 to 60, wherein the signal splitter is one of a 2-port signal splitter or a 3-port signal splitter.

Example 62 includes the wireless repeater of any of Examples 55 to 61, wherein the signal splitter is one or more of: a coupler, a tap, a resistive splitter, or a Wilkinson divider.

Example 63 includes the wireless repeater of any of Examples 55 to 62, wherein the signal splitter is integrated with the wireless repeater.

Example 64 includes the wireless repeater of any of Examples 55 to 63, wherein the first gain unit, the second gain unit and the signal splitter are coupled to a printed circuit board (PCB) of the wireless repeater.

Example 65 includes the wireless repeater of any of Examples 55 to 64, wherein one or more ports of the signal splitter are external to the wireless repeater.

Example 66 includes the wireless repeater of any of Examples 55 to 65, wherein: the first gain unit comprises one or more of an adjustable amplifier or an adjustable attenuator to control the first adjustable gain; or the second gain unit comprises one or more of an adjustable amplifier or an adjustable attenuator to control the second adjustable gain.

Example 67 includes the wireless repeater of any of Examples 55 to 66, wherein the first-direction signal is one of a downlink signal or an uplink signal, and the second-direction signal is one of a downlink signal or an uplink signal.

Example 68 includes the wireless repeater of any of Examples 55 to 67, further comprising: a first power level detector communicatively coupled to the first gain unit; a second power level detector communicatively coupled to the second gain unit; and a third power level detector communicatively coupled to the signal splitter, wherein the controller is further configured to identify the signal loss of the signal splitter based on a signal power level detected at the third power level detector in relation to a signal power level detected at the first power level detector or the second power level detector.

Example 69 includes the wireless repeater of any of Examples 55 to 68, wherein the first interface port is configured to be coupled to an access point antenna.

Example 70 includes the wireless repeater of any of Examples 55 to 69, wherein the second interface port is configured to be coupled to a first wireless device antenna or a communication device.

Example 71 includes the wireless repeater of any of Examples 55 to 70, wherein the third interface port is configured to be coupled to a second wireless device antenna or a communication device.

Example 72 includes a wireless repeater, comprising: a first interface port; a second interface port; a third interface port; a first gain unit with a first adjustable gain configured to be applied to a first-direction signal; a second gain unit with a second adjustable gain configured to be applied to a second-direction signal; a signal splitter comprising: a first splitter port; a second splitter port; and a third splitter port, wherein: the first gain unit and the second gain unit are communicatively coupled between the first interface port the first splitter port; the second splitter port is communicatively coupled to the second interface port; and the third splitter port is communicatively coupled to the third interface port; and a control unit communicatively coupled to the first gain unit and the second gain unit, the control unit configured to: control the first adjustable gain and the second adjustable gain to compensate for a signal loss of the signal splitter, wherein the first gain unit, the second gain unit and the signal splitter are integrated as a single contained unit within the wireless repeater.

Example 73 includes the wireless repeater of Example 72, wherein the signal splitter is a passive device.

Example 74 includes the wireless repeater of any of Examples 72 to 73, wherein the signal splitter is configured to combine a plurality of first-direction signals or a plurality of second-direction signals.

Example 75 includes the wireless repeater of any of Examples 72 to 74, wherein the control unit is configured to identify the signal loss of the signal splitter based on a known signal loss or a predetermined signal loss caused by the signal splitter.

Example 76 includes the wireless repeater of any of Examples 72 to 75, wherein the signal splitter is one of: a 2-port signal splitter, a 3-port signal splitter, or a 4-port signal splitter.

Example 77 includes the wireless repeater of any of Examples 72 to 76, wherein the 4-port signal splitter includes an access point port, a first wireless device port, a second wireless device port, a third wireless device port and a fourth wireless device port.

Example 78 includes the wireless repeater of any of Examples 72 to 77, wherein: the access point port is configured to be communicatively coupled to an access point antenna via the wireless repeater; the first wireless device port is configured to be communicatively coupled to a first wireless device antenna; the second wireless device port is configured to be communicatively coupled to a second wireless device antenna; the third wireless device port is configured to be communicatively coupled to a third wireless device antenna; and the fourth wireless device port is configured to be communicatively coupled to a fourth wireless device antenna.

Example 79 includes the wireless repeater of any of Examples 72 to 78, wherein the signal splitter is one or more of: a coupler, a tap, a resistive splitter, or a Wilkinson divider.

Example 80 includes the wireless repeater of any of Examples 72 to 79, wherein: the first gain unit comprises one or more of an adjustable amplifier or an adjustable attenuator to control the first adjustable gain; or the second gain unit comprises one or more of an adjustable amplifier or an adjustable attenuator to control the second adjustable gain.

Example 81 includes the wireless repeater of any of Examples 72 to 80, wherein the first-direction signal is one of a downlink signal or an uplink signal, and the second-direction signal is one of a downlink signal or an uplink signal.

Example 82 includes the wireless repeater of any of Examples 72 to 81, further comprising: a first power level detector communicatively coupled to the first gain unit; a second power level detector communicatively coupled to the second gain unit; and a third power level detector communicatively coupled to the signal splitter, wherein the controller is further configured to identify the signal loss of the signal splitter based on a signal power level detected at the third power level detector in relation to a signal power level detected at the first power level detector or the second power level detector.

Example 83 includes the wireless repeater of any of Examples 72 to 82, wherein the first interface port is configured to be coupled to an access point antenna.

Example 84 includes the wireless repeater of any of Examples 72 to 83, wherein the second interface port is configured to be coupled to a first wireless device antenna or a communication device.

Example 85 includes the wireless repeater of any of Examples 72 to 84, wherein the third interface port is configured to be coupled to a second wireless device antenna or a communication device.

It should be understood that the foregoing relates only to the exemplary embodiments of the present invention, and that numerous changes may be made therein without departing from the spirit and scope of the invention as defined by the following claims.

The invention claimed is:

1. A wireless repeater, comprising:
a first interface port;
a second interface port;
a front-end booster;
a main booster;
a first gain unit of the main booster, the first gain unit having a first adjustable gain configured to be applied to a first-direction signal;
a second gain unit of the main booster, the second gain unit having a second adjustable gain configured to be applied to a second-direction signal;
a first antenna configured to be coupled to the second interface port;
a second antenna configured to be coupled to the first interface port;
a coaxial cable communicatively coupled between the first front-end booster and the main booster; and
a control unit communicatively coupled to the first gain unit and the second gain unit of the main booster, the control unit configured to:
control the first adjustable gain or the second adjustable gain of the main booster to provide the first adjustable gain or the second adjustable gain at a level greater than a regulatory gain limit for the main booster to compensate for a signal loss of the coaxial cable to set the first adjustable gain at the second interface port and the second adjustable gain at the first interface port.

2. The wireless repeater of claim 1, wherein the front-end booster includes a first attenuator configured to be applied to the first-direction signal or a second attenuator configured to be applied to the second-direction signal.

3. The wireless repeater of claim 2, wherein the first attenuator is configured to set the gain of the first direction signal to a predetermined amount at the second interface port.

4. The wireless repeater of claim 2, wherein the second attenuator is configured to set the gain of the second direction signal to a predetermined amount at the first interface port.

5. The wireless repeater of claim 1, wherein a gain of the front-end booster for the first-direction signal and the second-direction signal is less than or equal to one.

6. A wireless repeater, comprising:
a first interface port;
a second interface port;
a main booster;
a first gain unit of the main booster, the first gain unit having a first adjustable gain configured to be applied to a first-direction signal;
a second gain unit of the main booster, the second gain unit having a second adjustable gain configured to be applied to a second-direction signal;
a first antenna configured to be coupled to the second interface port;
a second antenna configured to be coupled to the first interface port;
a first coaxial cable communicatively coupled between the main booster and the second interface port;
a second coaxial cable communicatively coupled between the main booster and the first interface port; and
a control unit communicatively coupled to the first gain unit and the second gain unit of the main booster, the control unit configured to:
control the first adjustable gain of the main booster to provide the first adjustable gain at a level greater than a regulatory gain limit for the main booster to compensate for a signal loss of the first coaxial cable to set the first adjustable gain at the second interface port or
control the second adjustable gain of the main booster to provide the second adjustable gain at a level greater than a regulatory gain limit for the main booster to compensate for a signal loss of the second coaxial cable to set the second adjustable gain at the first interface port.

7. The wireless repeater of claim 6, further comprising a front end booster and a coaxial cable communicatively coupled between the first front-end booster and the main booster.

8. The wireless repeater of claim 7, wherein the front-end booster includes a first attenuator configured to be applied to the first-direction signal and a second attenuator configured to be applied to the second-direction signal.

9. The wireless repeater of claim 8, wherein the first attenuator is configured to set the gain of the first direction signal to a predetermined amount at the second interface port.

10. The wireless repeater of claim 8, wherein the second attenuator is configured to set the gain of the second direction signal to a predetermined amount at the first interface port.

11. A wireless repeater, comprising:
a main booster;
a first gain unit of the main booster, the first gain unit having a first adjustable gain configured to be applied to a first-direction signal;
a second gain unit of the main booster, the second gain unit having a second adjustable gain configured to be applied to a second-direction signal;
a front end booster communicatively coupled to the main booster;
a first antenna communicatively coupled to the front-end booster;
a second antenna communicatively coupled to the main booster;
a coaxial cable communicatively coupled between the front end booster and the first antenna, or the coaxial cable is coupled between the main booster and the second antenna or the coaxial cable is communicatively coupled between the main booster and the front end booster; and
a control unit configured to adjust one or more of the first gain unit and the second gain unit of the main booster based on a signal loss of the coaxial cable.

12. The wireless repeater of claim 11, wherein the front-end booster includes a first attenuator configured to be applied to the first-direction signal and a second attenuator configured to be applied to the second-direction signal.

13. The wireless repeater of claim 11, further comprising:
a test signal generator configured to generate a direct current (DC) test signal or a radio frequency (RF) test signal to determine a signal loss of the coaxial cable.

14. The wireless repeater of claim 11, wherein the signal loss of the coaxial cable is determined for an RF operating frequency of the wireless repeater.

15. The wireless repeater of claim 11, wherein a gain of the front-end booster for the first-direction signal or the second-direction signal is less than or equal to one.

16. The wireless repeater of claim 11, wherein the control unit is configured to adjust the one or more of the first gain unit and the second gain unit of the main booster based on a predetermined signal loss of the coaxial cable.

17. The wireless repeater of claim 13, wherein one or more of the first adjustable gain or the second adjustable gain is adjusted based on the determined signal loss of the coaxial cable.

18. The wireless repeater of claim 11, further comprising:
a first interface port coupled to the main booster and configured to be coupled to the second antenna; and
a second interface port coupled to the front end booster and configured to be coupled to the first antenna;
wherein the control unit is configured to control the first adjustable gain or the second adjustable gain of the main booster to provide the first adjustable gain or the second adjustable gain at a level greater than a regulatory gain limit for the main booster to compensate for a signal loss of the first coaxial cable to set the first adjustable gain at the second interface port and to compensate for a signal loss of the second coaxial cable to set the second adjustable gain at the first interface port.

19. A wireless repeater, comprising:
a main booster;
a first gain unit of the main booster, the first gain unit having a first adjustable gain configured to be applied to a first-direction signal;
a second gain unit of the main booster, the second gain unit having a second adjustable gain configured to be applied to a second-direction signal;
a front end booster communicatively coupled to the main booster;
a first interface port communicatively coupled to the front-end booster;
a second interface port communicatively coupled to the main booster;
a coaxial cable communicatively coupled between the main booster and the front end booster; and
a test signal generator configured to generate a direct current (DC) test signal or a radio frequency (RF) test signal to determine a signal loss of the coaxial cable;
a control unit configured to adjust one or more of the first gain unit and the second gain unit of the main booster based on the determined signal loss of the coaxial cable.

20. The wireless repeater of claim 19, wherein the test signal generator is located in the front end booster.

21. The wireless repeater of claim 19, wherein the control unit is configured to control the first adjustable gain or the second adjustable gain of the main booster to provide the first adjustable gain or the second adjustable gain at a level greater than a regulatory gain limit for the main booster to compensate for a signal loss of the coaxial cable to set the first adjustable gain at the second interface port or to compensate for a signal loss of the coaxial cable to set the second adjustable gain at the first interface port.

22. The wireless repeater of claim 19, wherein the front-end booster includes a first attenuator configured to be applied to the first-direction signal or a second attenuator configured to be applied to the second-direction signal.

23. The wireless repeater of claim 22, wherein the first attenuator is configured to set the gain of the first direction signal to a predetermined amount at the second interface port.

24. The wireless repeater of claim 22, wherein the second attenuator is configured to set the gain of the second direction signal to a predetermined amount at the first interface port.

25. The wireless repeater of claim 19, wherein a gain of the front-end booster for the first-direction signal and the second-direction signal is less than or equal to one.

26. The wireless repeater of claim 19, wherein the signal loss of the coaxial cable is determined for an RF operating frequency of the wireless repeater.
